(19) United States
(12) Patent Application Publication
(10) Pub. No.: US 2025/0299992 A1
(43) Pub. Date: Sep. 25, 2025

(54) SUBSTRATE TRANSPORTING ROBOT, SUBSTRATE TREATING SYSTEM, AND METHOD OF CONTROLLING SUBSTRATE TRANSPORTING ROBOT

(71) Applicant: SCREEN Holdings Co., Ltd., Kyoto (JP)

(72) Inventors: Shinichi TANIGUCHI, Kyoto (JP); Hiroyuki KAWAHARA, Kyoto (JP)

(21) Appl. No.: 19/089,856

(22) Filed: Mar. 25, 2025

(30) Foreign Application Priority Data
Mar. 25, 2024 (JP) 2024-048247

(51) Int. Cl. H01L 21/677; H01L 21/687

(52) U.S. Cl. CPC H01L 21/67742; H01L 21/67745; H01L 21/67757; H01L 21/68707

(57) ABSTRACT

A substrate transporting robot includes a hand configured to support the substrate in a horizontal posture, an advancing and withdrawing mechanism and a linear moving mechanism configured to move the hand in a horizontal direction, and a robot controller. The robot controller causes the hand to support the substrate, on whose top face a liquid film is formed, to obtain a first range of an acceleration/deceleration for moving the hand in correspondence to a state of the liquid film, and causes at least either the advancing and withdrawing mechanism or the linear moving mechanism to move the hand at an acceleration/deceleration within the first range.

### CROSS-REFERENCE TO RELATED APPLICATIONS

This application claims priority to Japanese Patent Application No. 2024-048247 filed Mar. 25, 2024, the subject matter of which is incorporated herein by reference in entirety.

### TECHNICAL FIELD

The present invention relates to a substrate transporting robot that transports a substrate in a horizontal posture, a substrate treating system equipped with the robot, and a method of controlling the substrate transporting robot. Examples of substrates include semiconductor substrates, substrates for flat panel displays (FPDs), glass substrates for photomasks, substrates for optical disks, substrates for magnetic disks, ceramic substrates, and substrates for solar cells. Examples of the FPDs include liquid crystal display devices and organic electroluminescence (EL) display devices.

### BACKGROUND ART

A substrate treating system includes a transfer arm (substrate transfer robot) configured to transfer a substrate (see, for example, Japanese Patent Publications No. 2011-161521 and No. 2012-121680). The transfer arm includes a fork (hand) that is movable forward and backward. The fork includes four retaining claws for holding four points on a periphery of a substrate. Four strain sensors (strain gauges) are provided on the four retaining claws. The strain sensor detects an amount of strain of the retaining claw when a load is applied to the retaining claw from above.

Japanese Patent Publication No. H04-152654 discloses a wafer handling arm that can measure a load applied to a wafer support with a total of four load sensing elements. Japanese Patent Publication No. 2000-012430 discloses a substrate coating apparatus equipped with three lift pins that moves a substrate upward and downward and a weighing device that measures a weight of the substrate, the three lift pins, and a processing fluid while the substrate is lifted with the three lift pins. Moreover, Japanese Patent Publication No. 2016-217804 discloses a multi-axis tactile sensor.

Japanese Patent Publication No. 2024-001576 discloses a substrate treating apparatus (substrate treating system) that employs a treating method that combines a batch type and a single-wafer type (so-called hybrid method). The batch type is a method in which a plurality of substrates in vertical postures are treated in a batch. The single-wafer type is a method in which a single substrate W in a horizontal posture is treated.

### SUMMARY OF INVENTION

### Technical Problem

In the substrate treating system in Japanese Patent Publication No. 2024-001576, if a substrate is dried after a treatment by a batch processing unit and by the time a treatment is performed in a single-wafer processing unit, there is a risk that patterns formed on the substrate will collapse. Therefore, in order to prevent the substrate from being dried, the substrate is transported in a horizontal posture with a liquid is piled up on a top face of the substrate on which the patterns are formed. Here, it is undesirable that the liquid piled on the top face of the substrate is spilled during transportation since the substrate may be dried, for example.

The present invention has been made regarding the state of the art noted above, and its object is to provide a substrate transporting robot, a substrate treating system, and a method of controlling the substrate transporting robot that can prevent liquid from spilling from a top face of a substrate during transportation.

### Solution to Problem

The present invention is constituted as stated below to achieve the above object. That is, one aspect of the present invention provides a substrate transporting robot that transports a substrate, including a hand configured to support the substrate in a horizontal posture, a moving mechanism configured to move the hand in a horizontal direction, and a controller. The controller causes the hand to support the substrate, on whose top face a liquid film is formed, to obtain a first range of an acceleration/deceleration for moving the hand in correspondence to a state of the liquid film, and causes the moving mechanism to move the hand at an acceleration/deceleration within the first range.

According to the substrate transporting robot of the present invention, the first range of the acceleration/deceleration for moving the hand is obtained in correspondence to the state of the liquid film. The hand is moved at the acceleration/deceleration within the first range. This prevents a liquid from spilling from the top face of the substrate during transportation.

Moreover, it is preferred that the substrate transporting robot described above further includes a sensor configured to detect the state of the liquid film. The controller is configured to obtain the first range of the acceleration/deceleration for moving the hand in correspondence to a state of the liquid film detected by the sensor.

The substrate transporting robot includes the sensor that detects the state of the liquid film. Accordingly, the controller can obtain the first range of an acceleration/deceleration that takes into account an actual state of the liquid film detected by the sensor. This can enhance an accuracy of the first range of the acceleration/deceleration.

Moreover, it is preferred in the substrate transporting robot that the sensor is a weight sensor provided on the hand and configured to measure a weight. The controller is configured to obtain the first range of the acceleration/deceleration for moving the hand in correspondence to a weight of the liquid film measured by the weight sensor.

The substrate transporting robot includes the weight sensor as the sensor that detects the state of the liquid film. The weight sensor is provided on the hand. Accordingly, the controller can obtain the first range of the acceleration/deceleration that takes into account the weight of the liquid film measured by the weight sensor. In addition, the weight sensor is relatively small and relatively inexpensive. Accordingly, the hand is less likely to be large even if the weight sensor is provided on the hand. Therefore, space or cost issues are less likely to arise.

Moreover, examples of the hand in the substrate transporting robot described above include one having a hand body and a plurality of contacting parts on an upper surface of the hand body that receive a peripheral portion of the substrate, and examples of the weight sensor include one provided between any one of the contacting parts and the hand body. The contacting parts receive the peripheral portion of the substrate. Accordingly, the weight sensor can measure a weight at a position of any one of the contacting parts. Moreover, the first range of the acceleration/deceleration can be obtained from the weight measured at the position.

Moreover, it is preferred in the substrate transporting robot described above that the first range of the acceleration/deceleration is within a tolerance of the acceleration/deceleration narrower than a limit range of the acceleration/deceleration where the liquid does not spill from the substrate due to movement of the liquid of the liquid film, and that the controller monitors a weight change amount of the liquid moving on the top face of the substrate at a measurement position of the weight sensor during movement of the hand in accordance with a weight value measured by the weight sensor, and controls the acceleration/deceleration of the hand so that the weight change amount falls within a range of the change amount in correspondence to the tolerance of the acceleration/deceleration.

The limit range of the acceleration/deceleration is the range where the liquid does not spill from the substrate. Moreover, the tolerance of the acceleration/deceleration is narrower than the limit range. Accordingly, if the obtained acceleration/deceleration falls within the tolerance, no liquid spillage will occur. On the other hand, a relationship between the obtained tolerance and the change amount range may change due to some factors. In this case, a possibility of liquid spillage increases. Even in such a case, the weight change amount is adjusted to fall within the change amount range if the weight change amount is out of the change amount range as a threshold. This can prevent liquid spillage.

Moreover, it is preferred in the substrate transporting robot described above that the controller obtains the first range of the acceleration/deceleration for moving the hand in correspondence to the state of the liquid film and type of the substrate. The first range of the acceleration/deceleration for moving the hand is obtained in correspondence to the type of the substrate and the state of the liquid film. The hand is moved at the acceleration/deceleration within the first range. This prevents a liquid from spilling from the top face of the substrate during transportation.

Moreover, it is preferred in the substrate transporting robot described above that the type of the substrate include substrate wettability. Since the first range of the acceleration/deceleration is a range where the wettability of the substrate W is taken into account, the accuracy of the tolerance of the acceleration/deceleration can be enhanced.

Moreover, it is preferred in the substrate transporting robot described above that the controller obtains the first range of the acceleration/deceleration for moving the hand in correspondence to the state of the liquid film and type of the substrate using a lookup table. The lookup table makes it easy to obtain the first range of the acceleration/deceleration.

Moreover, it is preferred that the substrate transporting robot described above further includes a sensor configured to detect the state of the liquid film and a memory configured to store a plurality of pieces of relationship data, each of which differs in the state of the liquid film, and each of the plurality of pieces of relationship data has a relation between an amount of change in the state of the liquid film and the acceleration/deceleration and the first range of acceleration/deceleration in the relation. The controller is configured to obtain the amount of change in the state of the liquid film, detected by the sensor, when the moving mechanism moves the hand at a preset acceleration/deceleration, matches the preset acceleration/deceleration and the obtained amount of change in the state of the liquid film with the relation of the plurality of pieces of relational data, thereby extracting one piece of the relational data having the optimal relation from the plurality of pieces of relational data, and obtain the first range of the acceleration/deceleration that the one piece of the relation data has.

For example, even if conditions for the type of the substrate is insufficiently provided, the optimal (approximate) relational data can be obtained from the plurality of pieces of relational data already owned, and the first range of the acceleration/deceleration that the relational data has can be obtained.

Moreover, it is preferred that the substrate transporting robot described above further includes a rotation mechanism configured to rotate the hand around a vertical axis, and the controller obtains a second range of a rotation acceleration/deceleration for rotating the hand in correspondence to the state of the liquid film, and causes the rotation mechanism to rotate the hand within the second range.

According to the substrate transporting robot of the present invention, the second range of the rotation acceleration/deceleration for moving the hand in correspondence to the state of the liquid film is obtained, and the hand is moved at a rotation acceleration/deceleration within the second range. This prevents a liquid from spilling from the top face of the substrate during transportation (especially, rotation).

Moreover, another aspect of the present invention provides a substrate treating system that treats a substrate, the substrate treating system including the substrate transporting robot described above.

Another aspect of the present invention provides a method of controlling a substrate transporting robot that transports a substrate, the substrate transporting robot including a hand configured to support the substrate in a horizontal posture, and a moving mechanism configured to move the hand in a horizontal direction. The method includes a step of causing the hand to support the substrate, on whose top face a liquid film is formed, obtaining a first range of an acceleration/deceleration for moving the hand in correspondence to a state of the liquid film, and causing the moving mechanism to move the hand at an acceleration/deceleration within the first range.

### Advantageous Effects of Invention

With the substrate transporting robot, the substrate treating system, and the method of controlling the substrate transporting robot according to the present invention, the liquid can be prevented from spilling from the top face of the substrate during transportation.

### BRIEF DESCRIPTION OF DRAWINGS

For the purpose of illustrating the invention, there are shown in the drawings several forms which are presently preferred, it being understood, however, that the invention is not limited to the precise arrangement and instrumentalities shown.

FIG. 1 is a plan view schematically illustrating a configuration of a substrate treating system according to a first embodiment.

FIGS. 2A to 2C are each a side view illustrating configurations and operations of a substrate handling mechanism and a first posture turning mechanism.

FIG. 3 is a plan view of a second posture turning mechanism.

FIG. 4 is a longitudinal sectional view of a rotary chuck seen from an arrow Q in FIG. 3.

FIG. 5 is a side view schematically illustrating a configuration of a substrate transporting robot.

FIG. 6 is a plan view of a hand.

FIG. 7A is a plan view to illustrate movement of a liquid in backward movement of the hand, and FIG. 7B illustrates detection waveforms of four weight sensors.

FIG. 8A is a plan view to illustrate movement of a liquid in rotation of the hand, and FIG. 8B illustrates detection waveforms of the four weight sensors.

FIG. 9A is a plan view to illustrate movement of a liquid in forward movement of the hand, and FIG. 9B illustrates detection waveforms of four weight sensors.

FIG. 10 is a view to illustrate a relationship between a weight change amount of the liquid and one of an acceleration/deceleration and a rotation acceleration/deceleration.

FIG. 11 is a view illustrating one example of a lookup table.

FIG. 12 is a view illustrating one example of a relationship between the acceleration/deceleration and the weight change amount of the liquid in a case of a hydrophilic substrate.

FIG. 13 is a view illustrating one example of a relationship between the acceleration/deceleration and the weight change amount of the liquid in a case of a hydrophobic substrate.

FIG. 14 is a flowchart to illustrate operation of the substrate treating system.

FIGS. 15A to 15C are each a side view illustrating operation of the second posture turning mechanism.

FIGS. 16A to 16C are each a side view illustrating operation of the second posture turning mechanism.

FIG. 17 is a flowchart to illustrate operation of the substrate transporting robot.

FIG. 18 is a plan view to illustrate operation of the substrate transporting robot.

FIG. 19 is a view of detection waveforms of weight sensors to illustrate operation of a substrate transporting robot according to a second embodiment.

FIG. 20A is a side view to illustrate a camera as a sensor in a modification, and FIG. 20B is a view illustrating an overall image of a substrate in which a state of a liquid film is captured and four images of interest.

FIG. 21 is a side view to illustrate a film thickness meter as a sensor according to another modification.

FIG. 22 is a view to illustrate a method of obtaining a tolerance of an acceleration/deceleration according to still another modification.

### DESCRIPTION OF EMBODIMENTS

The present invention will be described below with various embodiments.

### First Embodiment

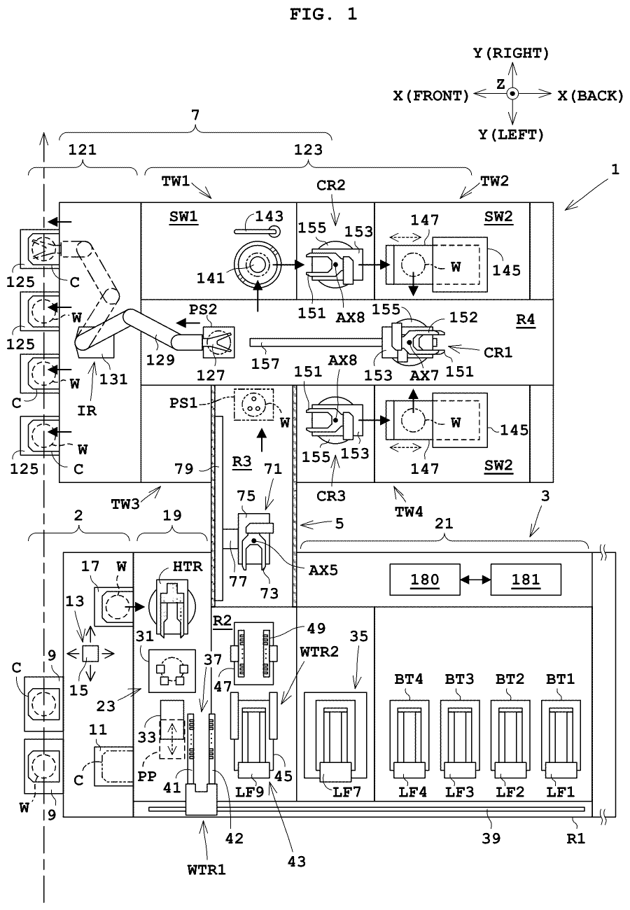

A first embodiment of the present invention will now be described with reference to the drawings. FIG. 1 is a plan view schematically illustrating a configuration of a substrate treating system 1 according to the first embodiment.

In the present specification, a direction in which a transferring block 19 and a treating block 21 are arranged is referred to as a “front-back direction X” for convenience. The front-back direction X is horizontal. One direction of the front-back direction X from the treating block 21 to the transferring block 19, for example, is referred to as “forward”. The direction opposite to forward is referred to as “rearward”. A horizontal direction orthogonal to the front-back direction X is referred to as a “transverse direction Y”. Moreover, one direction of the transverse direction Y is referred to as “rightward”, as appropriate. The direction opposite to rightward is referred to as “leftward”. A perpendicular direction relative to the horizontal direction is referred to as a “vertical direction Z”. For reference, the drawings show front, rear, right, left, up, and down, as appropriate.

### 1. Construction of Substrate Treating System

Reference is made to FIG. 1. The substrate treating system 1 treats substrates W. The substrate treating system 1 performs chemical liquid treatment, cleaning treatment, dry treatment, and the like, for example, on the substrates W. The substrate treating system 1 performs batch treatment for processing a plurality of (e.g., twenty-fir or fifty) substrates W collectively and a single-wafer processing for processing the substrates W one by one. Accordingly, the substrate treating system 1 is called a hybrid type of substrate treating system. This embodiment describes a case where twenty-five substrates W are treated collectively.

The substrate treating system 1 includes a stocker 2, a batch processing device 3, a relay device 5, and a single-wafer processing device 7. The batch processing device 3 treats the substrates W collectively. The single-wafer processing device 7 treats the substrates W one by one. The single-wafer processing device 7 is located rightward of the batch processing device 3 and away from the batch processing device 3. The relay device 5 connects the batch processing device 3 and the single-wafer processing device 7.

### 2. Stocker

The stocker 2 accommodates at least one carrier C. The stocker 2 is adjacent to a front side of the batch processing device 3. The carrier C accommodates a plurality of (e.g., twenty-five) substrates W aligned at a predetermined interval (e.g., 10 mm) in horizontal postures. A front opening unify pod (FOUP) is used as the carrier C, for example, but is not limited to this. For example, a circular substrate W having a diameter of 300 mm is used.

The stocker 2 includes two load ports 9, at least one storage shelf 11, and a carrier transport robot 13, for example. The storage shelf 11 has the carrier C placed thereon.

The carrier transport robot 13 transports the carrier C among the two load ports 9, the storage shelf 11, and a mount shelf 17 to be mentioned later. The carrier transport robot 13 includes a gripper 15 that grips a projection provided on an upper surface of the carrier C, for example. The carrier transport robot 13 can move the gripper 15 in the horizontal direction (front-back direction X and transverse direction Y) and the vertical direction Z. The carrier transport robot 13 is driven by one or more electric motors.

### 3. Batch Processing Device

The batch processing device 3 includes the mount shelf 17, a transferring block 19, a treating block 21, and a batch transport region R1. The mount shelf 17 is adjacent to a front side of the transferring block 19. The treating block 21 is located rearward of the transferring block 19 via a posture turning region R2 to be mentioned later. The batch transport region R1 extends rearward from the transferring block 19. The batch transport region R1 is adjacent to left sides of the transferring block 19, the treating block 21, and the posture turning region R2.

### 3-1. Transferring Block

The transferring block 19 includes a substrate handling mechanism (robot) HTR and a first posture turning mechanism 23. The substrate handling mechanism HTR is provided rearward of the mount shelf 17. The substrate handling mechanism HTR transports a plurality of (e.g., twenty-five) substrates W in horizontal postures between the carrier C placed on the mount shelf 17 and the first posture turning mechanism 23.

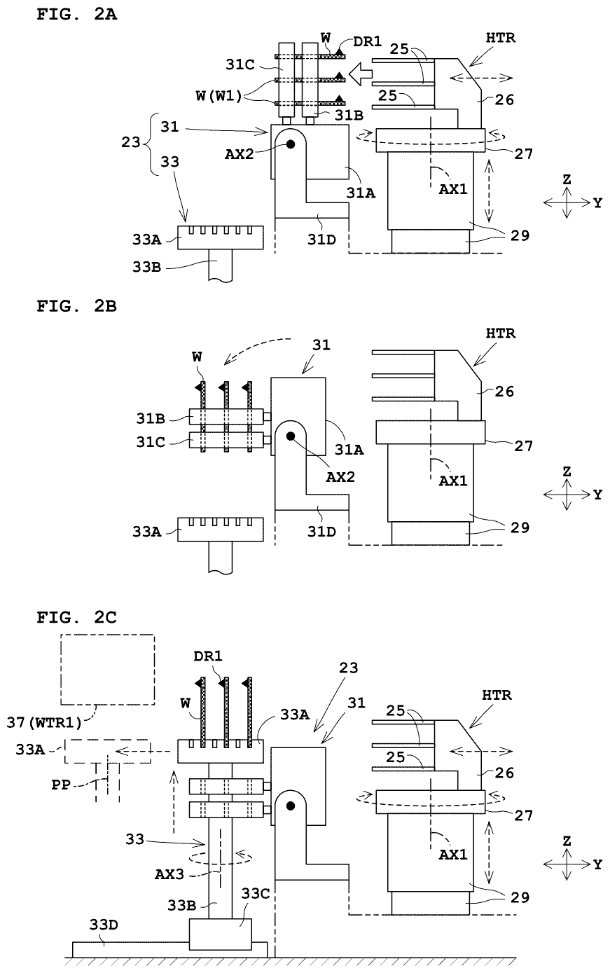

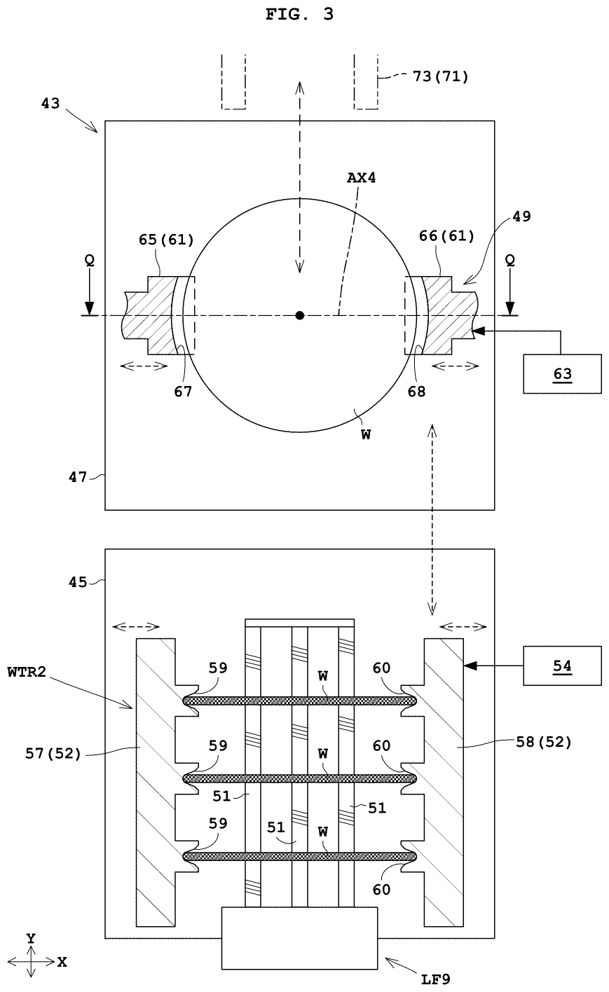

Reference is made to FIGS. 2A to 2C. The substrate handling mechanism HTR includes a plurality of (e.g., twenty-five) hands 25. The hands 25 each hold one substrate W. Here in FIGS. 2A to 2C, the substrate handling mechanism HTR includes three hands 25 for convenience of illustration. Moreover, it is assumed that one-paired horizontal holders 31B and one-paired vertical holders 31C, to be mentioned later, hold three substrates W. Moreover, it is assumed that a pusher member 33A, to be mentioned later, holds three substrates W.

The substrate handling mechanism HTR further includes a hand supporting portion 26, an advancing and withdrawing mechanism 27, and a lifting and rotating mechanism 29. The hand supporting portion 26 supports the plurality of hands 25. The advancing and withdrawing mechanism 27 causes the hands 25 to advance and withdraw via the hand supporting portion 26. The lifting and rotating mechanism 29 rotates the advancing and withdrawing mechanism 27 around a vertical axis AX1 so as to change an orientation of the hands 25. Here, the advancing and withdrawing mechanism 27 and the lifting and rotating mechanism 29 each include an electric motor.

The first posture turning mechanism 23 includes a posture turning unit 31 and a pusher mechanism 33. The substrate handling mechanism HTR, the posture turning unit 31, and the pusher mechanism 33 are arranged leftward in this order. The posture turning unit 31 receives the substrates W from the substrate handling mechanism HTR and turns the substrates W from the horizontal posture to the vertical posture.

As shown in FIG. 2A, the posture turning unit 31 includes a support base 31A, one-paired horizontal holders 31B, one-paired vertical holders 31C, and a rotation driving mechanism 31D. The one-paired horizontal holders 31B and the one-paired vertical holders 31C are provided on the support base 31A. When the substrates W are in the horizontal postures, the one-paired horizontal holders 31B support the substrates W from below while contacting a lower face of each of the substrates W. In contrast to this, when the substrates W are in the vertical postures, the one-paired vertical holders 31C hold the substrates W. The rotation driving mechanism 31D rotates the support base 31A around a horizontal axis AX2.

As illustrated in FIG. 2C, the pusher mechanism 33 includes a pusher member 33A, a lifting and rotating mechanism 33B, a horizontally moving mechanism 33C, and a rail 33D. The pusher member 33A supports a lower part of each of the plurality of (e.g., twenty-five or fifty) substrates W whose postures are turned to the vertical postures by the posture turning unit 31. The lifting and rotating mechanism 33B moves the pusher member 33A upward and downward in the vertical direction Z. Moreover, the lifting and rotating mechanism 33B rotates the pusher member 33A around a vertical axis AX3. This can change orientation of device faces of the substrates W, shown by a numeral DR1, to any directions.

The horizontally moving mechanism 33C moves the pusher member 33A and the lifting and rotating mechanism 33B horizontally along the rail 33D. The rail 33D extends in the transverse direction Y. The rotation driving mechanism 31D, the lifting and rotating mechanism 33B, and the horizontally moving mechanism 33C each include an electric motor.

Description is now made of operation of the first posture turning mechanism 23. Reference is made to FIG. 2A. The posture turning unit 31 receives twenty-five substrates W from the substrate handling mechanism HTR. Device faces of the substrates W are each directed upward. Here, a device face of a substrate W is a surface where electronic circuits are formed, and includes a surface in the process of forming electronic circuits. The device face is also referred to as a “front face” or “main face”. Moreover, a back face of the substrate W is a face where no electronic circuits are formed. A face opposite to the device face corresponds to the back face.

Reference is made to FIG. 2B. The rotation driving mechanism 31D of the posture turning unit 31 rotates the one-paired horizontal holders 31B and the like by 90 degrees around the horizontal axis AX2 to turn the postures of the twenty-five substrates W from horizontal to vertical.

Reference is made to FIG. 2C. Thereafter, the pusher mechanism 33 moves the pusher member 33A upward and receives the twenty-five substrates W from the posture turning unit 31. The pusher member 33A holds the twenty-five substrates W. Thereafter, the pusher mechanism 33 moves the pusher member 33A, holding the twenty-five substrates W, to a substrate delivery position PP below a chuck 37 (mentioned later) of a first batch transport robot WTR1 (mentioned later) along the rail 33D.

### 3-2. Treating Block

Reference is made to FIG. 1. The treating block 21 includes a plurality of (e.g., four) batch process tanks BT1 to BT4 and a batch drying unit 35. The four batch process tanks BT1 to BT4 and the batch drying unit 35 are arranged in the front-back direction X where the batch processing device 3 extends. Each of the four batch process tanks BT1 to BT4 performs immersion treatment to a plurality of (e.g., twenty-five or fifty substrates) substrates W collectively. Each of the four batch process tanks BT1 to BT4 stores a treatment liquid (e.g., chemical liquid or pure water) for the immersion treatment to the substrates W.

The four batch process tanks BT1 to BT4 are formed by two chemical liquid process tanks BT1, BT2 and two cleaning process tanks BT3 and BT4, for example. The number of batch process tanks is not limited to four, and the number only needs to be one or more. Arrangement and roles of the four batch process tanks BT1 to BT4 are not limited.

The two chemical liquid process tanks BT1, BT2 each perform etching treatment with a chemical liquid. A phosphoric acid solution is used as the chemical liquid, for example. A chemical liquid jet pipe, not shown, is provided at an inner bottom of each of the chemical liquid process tanks BT1 and BT2. The chemical liquid process tanks BT1, BT2 each store the chemical liquid supplied from the chemical liquid jet pipe.

The two cleaning process tanks BT3, BT4 each perform cleaning treatment by cleaning off the chemical liquid, adhered to the substrates W, with a cleaning liquid (rinse liquid). Pure water like deionized water (DIW), for example, is used as the cleaning liquid. The cleaning process tanks BT3, BT4 each store pure water supplied from a pure water jet pipe, not shown. The four batch process tanks BT1 to BT4 contain four lifters LF1 to LF4, respectively. For example, the lifter LF1 holds twenty-five substrates W in the vertical postures arranged in the transverse direction Y. The lifter LF1 can immerse the twenty-five substrates W in the chemical liquid in the batch process tank BT1 while holding the twenty-five substrates W in the vertical postures. The lifter LF1 moves the substrates W upward and downward between a treating position inside of the batch process tank BT1 and a delivery position above the batch process tank BT1. The other three lifters LF2 to LF4 are configured in the same manner as the lifter LF1.

The batch drying unit 35 dries a plurality of substrates W collectively. The batch drying unit 35 is used, for example, when the single-wafer processing device 7 is not available. The batch drying unit 35 is provided between the transferring block 19 and the four batch process tanks BT1 to BT4. The batch drying unit 35 includes a lifter LF7. The batch drying unit 35 dries a substrate W by supplying an organic solvent (e.g., isopropyl alcohol) to the substrate W in a reduced-pressure atmosphere or by scattering liquid components on a surface of the substrate W with centrifugal force.

### 3-3. Batch Transport Region

The batch transport region R1 has a first batch transport robot WTR1. The first batch transport robot WTR1 transports a plurality of substrates W in vertical postures among the first posture turning mechanism 23 (including pusher mechanism 33), the four lifters LF1 to LF4, the relay device 5 (second posture turning mechanism 43 mentioned later), and the lifter LF7 of the batch drying unit 35.

The first batch transport robot WTR1 includes a chuck 37 and a guide rail 39. The chuck 37 includes two chuck members 41, 42. The two chuck members 41, 42 each extend in the transverse direction Y. The two chuck members 41, 42 have twenty-five-paired holding grooves for holding twenty-five substrates W, for example. The first batch transport robot WTR1 opens and closes the two chuck members 41, 42. The guide rail 39 extends in the front-back direction X. The first batch transport robot WTR1 moves the chuck 37 along the guide rail 39. The first batch transport robot WTR1 is driven by an electric motor.

### 4. Relay Device (Interface Device)

The relay device 5 turns postures of the substrates W treated in either of the two chemical liquid process tanks BT1 or BT2 from vertical to horizontal, and also delivers the substrates W whose postures are turned to horizontal to the single-wafer processing device 7.

As shown in FIG. 1, the relay device 5 includes a posture turning region R2 and a relay region R3 arranged in the transverse direction Y. The relay region R3 extends rightward from the posture turning region R2. In the front-back direction X, the posture turning region R2 is located between the first posture turning mechanism 23 in the transferring block 19 and the four batch process tanks BT1 to BT4 in the treating block 21. Moreover, a left part of the relay region R3 is located between the transferring block 19 and the treating block 21.

### 4-1. Second Posture Turning Mechanism

The posture turning region R2 contains a second posture turning mechanism 43. As shown in FIG. 1, the second posture turning mechanism 43 includes a stand-by tank 45, a stand-by lifter LF9, a second batch transport robot WTR2, a posture turning tank 47, and a posture turning unit 49.

FIG. 3 is a plan view of the second posture turning mechanism 43. Here in FIG. 3, one-paired chuck members 57, 58 of the second batch transport robot WTR2 are shown in cross-section. Moreover, one-paired chuck members 65, 66 of the posture turning unit 49 are shown in cross-section. In FIG. 3, the stand-by lifter LF9 holds three substrates W for convenience of illustration. A chuck 52 of the second batch transport robot WTR2 also holds three substrates W.

The stand-by tank 45 stores an immersion liquid in which the substrates W are immersed. Pure water (e.g., DIW) is used for the immersion liquid. Pure water is supplied from a pure water jet pipe, not shown.

The stand-by lifter LF9 receives a plurality of (e.g., twenty-five) substrates W from the first batch transport robot WTR1, and holds the substrates W in vertical postures. The stand-by lifter LF9 includes three support members 51, for example, that extend in the transverse direction Y. The three support members 51 each include a plurality of holding grooves aligned in the transverse direction Y for holding substrates W.

The second batch transport robot WTR2 transports a plurality of (e.g., twenty-five) substrates W between the stand-by lifter LF9 and a rotary chuck 61 of the posture turning unit 49. The second batch transport robot WTR2 includes a chuck 52 and a drive mechanism 54. The chuck 52 is movable in the transverse direction Y, and is openable and closable in the front-back direction X. The chuck 52 includes one-paired chuck members 57, 58. The one-paired chuck members 57, 58 include plural-paired (e.g., twenty-five-paired) holding grooves 59, 60, respectively. The paired holding grooves 59, 60 are opposite to each other.

The drive mechanism 54 moves the chuck 52 in the transverse direction Y. The drive mechanism 54 also opens and closes the chuck 52 (chuck members 57, 58) by moving the chuck 52 in the front-back direction X. Here in FIG. 3, the chuck 52 is closed. The drive mechanism 54 includes at least either an electric motor or an air cylinder, for example.

The posture turning tank 47 stores an immersion liquid in which the substrates W are immersed. Pure water (e.g., DIW) is used for the immersion liquid. Pure water is supplied from a pure water jet pipe, not shown. The posture turning tank 47 is located rightward of the stand-by tank 45 in the transverse direction Y.

The posture turning unit 49 turns postures of a plurality of (e.g., twenty-five) substrates W from vertical to horizontal in the immersion liquid stored in the posture turning tank 47. The posture turning unit 49 includes a rotary chuck 61 and a driving unit 63.

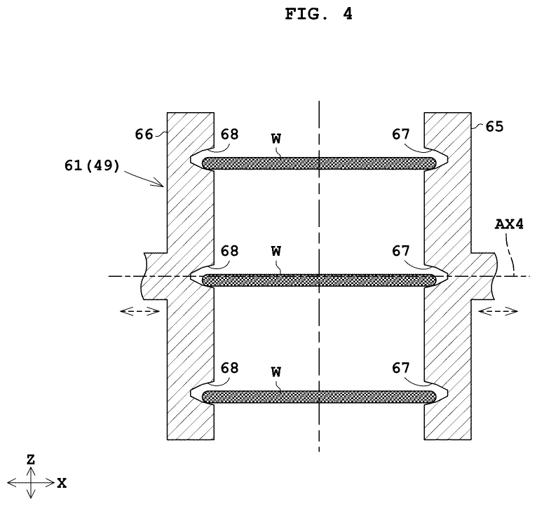

The rotary chuck 61 holds a plurality of (e.g., twenty-five) substrates W. The rotary chuck 61 includes one-paired chuck members 65, 66. As shown in FIG. 4, the one-paired chuck members 65, 66 includes plural-paired (e.g., twenty-five-paired) holding grooves 67, 68, respectively. The rotary chuck 61 (chuck members 65, 66) can open and close along a horizontal axis AX4 extending in the front-back direction X. Accordingly, when the rotary chuck 61 is closed, the rotary chuck 61 can hold a plurality of substrates W with the plural-paired holding grooves 67, 68. Here, FIG. 4 is a front view of the rotary chuck 61 seen from an arrow Q in FIG. 3. Also in FIGS. 3 and 4, the rotary chuck 61 is open. The rotary chuck 61 holds three substrates W for convenience of illustration.

The rotary chuck 61 can rotate about the horizontal axis AX4. The driving unit 63 of the posture turning unit 49 rotates the rotary chuck 61 around the horizontal axis AX4. This turns postures of a plurality of substrates W held by the rotary chuck 61 from vertical to horizontal. The driving unit 63 also opens and closes the rotary chuck 61 (chuck members 65, 66). The driving unit 63 also raises and lowers the rotary chuck 61. The driving unit 63 includes at least either an electric motor or an air cylinder, for example.

### 4-2. Substrate Transporting Robot

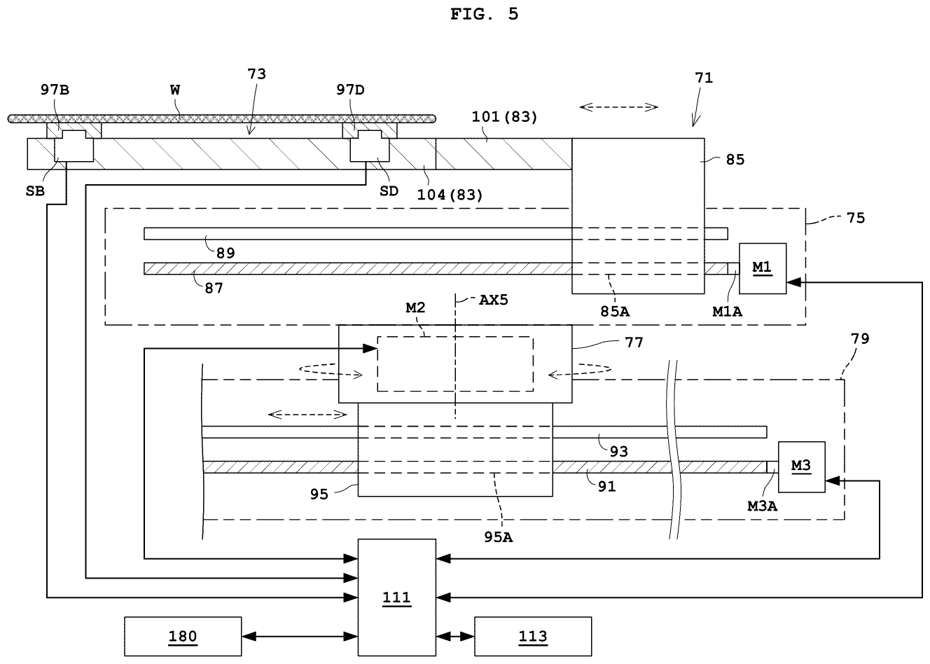

Reference is made to FIGS. 1 and 5. The relay region R3 contains a substrate transporting robot 71 that transports substrates W and a substrate platform PS1 (shelf) on which the substrates W are placed. The substrate transporting robot 71 corresponds to the substrate transporting robot in the present invention.

Now, the characteristic feature of the present embodiment is to be described. In the substrate treating system 1, if the substrate W is dried after a treatment by at least any of batch process tanks BT1 to BT4 and by the time a treatment is performed in either of the single-wafer processing chamber SW1, SW2 of the single-wafer processing device 7, there is a risk that patterns formed on the substrate W will collapse. Therefore, in order to prevent the substrate W from being dried, the substrate W is transported in a horizontal posture with a liquid is piled up (a liquid film is formed) on a top face of the substrate W on which the patterns are to be formed. Here, it is undesirable that the liquid piled on the top face of the substrate W is spilled during transportation since the substrate W may be dried, for example. Then, the present embodiment prevents a liquid from spilling from the top face of the substrate W during transportation.

### 4-2-1. Overall Construction of Substrate Transporting Robot

The substrate transporting robot 71 includes a hand 73, an advancing and withdrawing mechanism 75, a rotating mechanism 77, and a linear moving mechanism 79. The hand 73 supports one substrate W in a horizontal posture. The hand 73 includes a hand body 83 and a hand supporting portion 85. The hand supporting portion 85 is connected to a proximal end of the hand body 83. Detailed description of the hand 73 is to be made later.

The advancing and withdrawing mechanism 75 moves the hand 73 forward and backward. In other words, the advancing and withdrawing mechanism 75 moves the hand 73 horizontally. The advancing and withdrawing mechanism 75 includes an electric motor M1, a screw shaft 87, and a guide rail 89, for example. The screw shaft 87 extends linearly in any horizontal direction. The guide rail 89 extends parallel to the screw shaft 87. The hand supporting portion 85 is guided by the guide rail 89 in a direction where the guide rail 89 extends.

The screw shaft 87 engages with an internal thread 85A of the hand supporting portion 85. A first end of the screw shaft 87 is connected to an output shaft MIA of the electric motor M1. The electric motor M1 rotates the screw shaft 87 forward about its axis. Accordingly, the hand 73 is advanced. Moreover, the electric motor M1 rotates the screw shaft 87 rearward about its axis. Accordingly, the hand 73 is withdrawn.

The rotating mechanism 77 rotates the hand 73 and the advancing and withdrawing mechanism 75 around a vertical axis AX5. This can change orientations of the hand 73 and the advancing and withdrawing mechanism 75. The rotating mechanism 77 includes an electric motor M2, for example.

The linear moving mechanism 79 moves the hand 73, the advancing and withdrawing mechanism 75, and the rotating mechanism 77 in the transverse direction Y (horizontal direction). The linear moving mechanism 79 includes an electric motor M3, a screw shaft 91, a guide rail 93, and a slider 95, for example. The screw shaft 91 and the guide rail 93 extend in the transverse direction Y. The slider 95 is coupled to the rotating mechanism 77. The slider 95 is guided by the guide rail 93 in the transverse direction Y where the guide rail 93 extends.

The screw shaft 91 engages with an internal thread 95A of the slider 95. A first end of the screw shaft 91 is connected to an output shaft M3A of the electric motor M3. The electric motor M3 rotates the screw shaft 91 forward about its axis. Accordingly, the hand 73, the advancing and withdrawing mechanism 75, and the rotating mechanism 77 are advanced. In FIG. 1, for example, the hand 73 and the like are moved toward the posture turning unit 49. Moreover, the electric motor M1 rotates the screw shaft 87 rearward about its axis. Accordingly, the hand 73 and the like are withdrawn. In FIG. 1, for example, the hand 73 and the like are moved toward the substrate platform PS1.

### 4-2-2. Detailed Construction of Hand

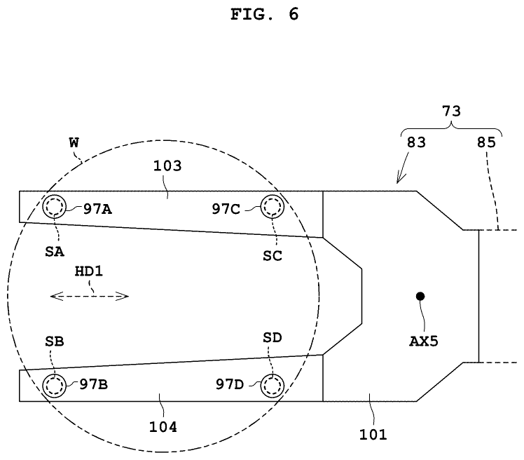

Reference is made to FIGS. 5 and 6. FIG. 6 is a plan view of the hand 73. The hand 73 further includes a plurality (e.g., four) of contacting parts 97A, 97B, 97C, 97D, and a plurality (e.g., four) of weight sensors SA, SB, SC, SD.

As shown in FIG. 6, the hand body 83 is formed in a U-shape or a Y-shape. Specifically, the hand body 83 has one palm portion 101 and two finger portions 103, 104. The two finger portions 103, 104 are both formed to extend from the palm portion 101 in a predetermined horizontal direction HD1. The finger portion 103 is located away from finger portion 104.

The four contacting parts 97A to 97D are provided on an upper surface of the hand body 83. The four contacting parts 97A to 97D each receive a peripheral portion of a substrate W. In other words, the substrate W is placed on the four contacting parts 97A to 97D. The four contacting parts 97A to 97D each contact against a lower face of the substrate W in the horizontal posture without contacting against a side face of the substrate W in the horizontal posture. The two contacting parts 97A and 97C are provided on an upper surface of the finger portion 103. The contacting part 97A is provided closer to a distal end side of the finger portion 103 than the contacting part 97C. The two contacting parts 97B and 97D are provided on an upper surface of the finger portion 104. The contacting part 97B is provided closer to a distal end side of the finger portion 104 than the contacting part 97D.

The four weight sensors SA, SB, SC, and SD are provided on the hand body 83 to correspond to the four contacting parts 97A, 97B, 97C, and 97D, respectively. That is, the four weight sensors SA, SB, SC, SD are provided between the four contacting parts 97A, 97B, 97C, and 97D, and the hand body 83, respectively. As shown in FIG. 5, the weight sensor SB is provided below or on a lower surface of the contacting part 97B. Moreover, the weight sensor SD is provided below or on a lower surface of the contacting part 97D. The weight sensors SA and SC are also provided in the same manner as the weight sensor SB (SD). The four weight sensors SA to SD may be embedded in the hand body 83.

The four weight sensors SA to SD are each a multi-axis tactile sensor (force sensor) of six-axis or three-axis, for example, but may also be a single-axis (Z-axis) load cell (tactile sensor). The six-axis tactile sensor is a sensor that can measure forces in the three axes (Fx, Fy, Fz) and moments in the three axes (Mx, My, Mz). A detection method of the tactile sensors is, for example, but not limited to, an electrical resistance type.

The four weight sensors SA to SD measure a weight of the substrate W and a liquid film formed on its top face. For example, four weight values (weight data) JA, JB, JC, and JD measured by the four weight sensors SA to SD, respectively, are sent to a robot controller 111. The robot controller 111 calculates the sum of the four weight data JA, JB, JC, and JD, for example. Accordingly, the robot controller 111 obtains an overall weight of the substrate W and the liquid film formed on its top face. Here, the robot controller 111 can recognize an amount of the liquid film (liquid volume) (ml; milliliters) from the weight of the liquid film which is obtained by subtracting the weight of the substrate W from the overall weight.

During transportation of the substrate W supported by the hand 73, the liquid of the liquid film formed on the top face of the substrate W moves. Accordingly, each of the four weight values JA to JD by the four weight sensors SA to SD change.

### 4-2-3. Robot Controller

The substrate transporting robot 71 includes the robot controller 111 and a memory unit 113. The robot controller 111 is communicatively connected to a main controller 180, which is described later. The robot controller 111 controls each component of the substrate transporting robot 71. The robot controller 111 includes one or more processors like a central processing unit (CPU). The memory unit 113 includes, for example, at least one of a read-only memory (ROM), a random-access memory (RAM), and a hard disk. The memory unit 113 stores computer programs necessary to control each component of the substrate transporting robot 71. Here, at least either the memory unit 113 or a memory unit 181 described later stores information on a type (e.g., wettability) of each substrate W stored in the carrier C.

### 4-2-4. Obtaining Tolerance of Acceleration/Deceleration and Rotation Acceleration/Deceleration

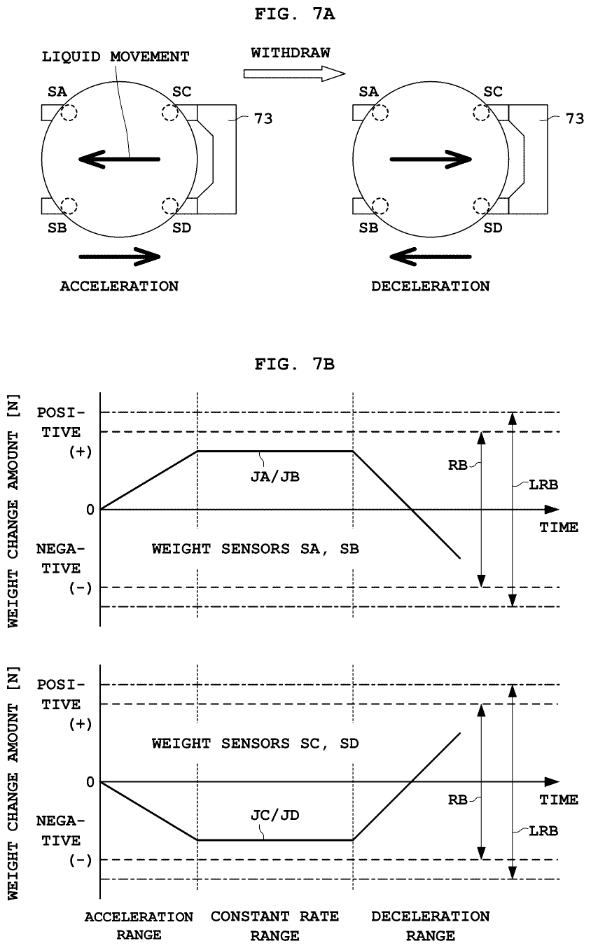

First, movement of the liquid and detection waveforms of the four weight sensors SA to SD are to be explained with reference to FIGS. 7A, 7B, 8A, 8B, 9A, and 9B. Here in FIGS. 7A, 8A, and 9A, the liquid film is formed on the top face of the substrate W held by the hand 73.

Reference is made to FIGS. 7A and 7B. It is assumed that the advancing and withdrawing mechanism 75 or the linear moving mechanism 79 moves the hand 73 backward. In this case, the liquid tends to move toward the weight sensors SA and SB in an acceleration range. Accordingly, weight values JA and JB measured by the weight sensors SA and SB, respectively, increase. In contrast to this, the weight values JC and JD measured by the weight sensors SC and SD, respectively, decrease. Moreover, the liquid tends to move toward the weight sensors SC and SD in a deceleration range. Therefore, the weight values JA and JB measured by the weight sensors SA and SB, respectively, decrease. In contrast to this, the weight values JC and JD measured by weight sensors SC and SD, respectively, increase. Here in FIGS. 7A and 7B, the rotating mechanism 77 does not rotate the hand 73 around the vertical axis AX5.

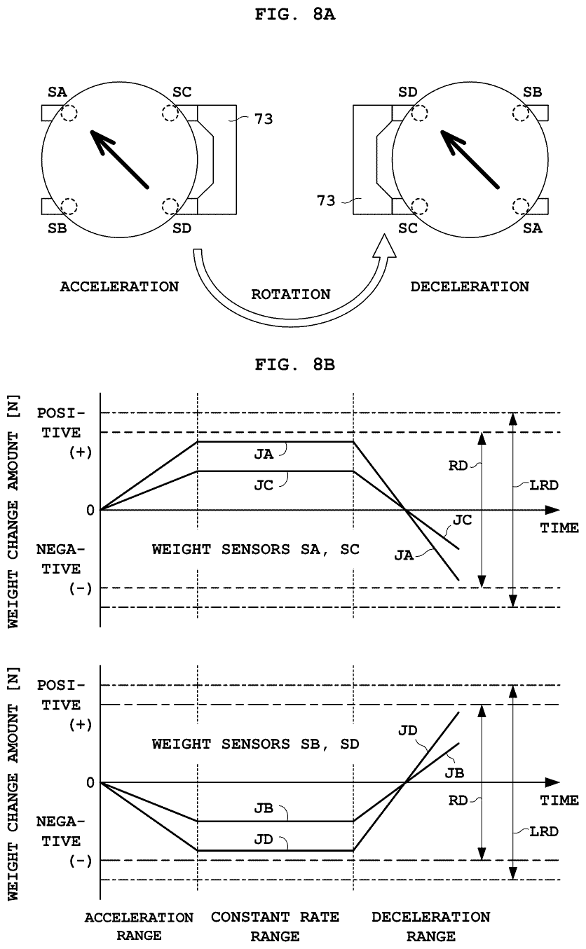

Reference is made to FIGS. 8A and 8B. It is assumed that the rotating mechanism 77 rotates the hand 73 counterclockwise around the vertical axis AX5. In this case, the liquid tends to move toward the weight sensors SA and SC in the acceleration range. In addition, the centrifugal force increases, so that the liquid tends to move closer to the weight sensor SA than the weight sensor SC. Accordingly, weight values JA and JC measured by the weight sensors SA and SC, respectively, increase. Moreover, the weight value JA (weight change amount) is larger than the weight value JC. In contrast to this, the weight values JB and JD measured by the weight sensors SB and SD, respectively, decrease. Moreover, the weight value JD (weight change amount) is smaller than the weight value JB.

Moreover, the liquid tends to move toward the weight sensors SB and SD in a deceleration range. In addition, the centrifugal force decreases, so that the liquid tends to move closer to the weight sensor SD than the weight sensor SB. Accordingly, weight values JA and JC measured by the weight sensors SA and SC, respectively, decrease. In addition, a rate of decrease in the weight value JA (weight change amount) is larger than that of the weight value JC. In contrast to this, the weight values JB and JD measured by the weight sensors SB and SD, respectively, increase. In addition, a rate of increase in the weight value JD (weight change amount) is larger than that of the weight value JB. Here in FIGS. 8A and 8B, neither the advancing and withdrawing mechanism 75 nor the linear moving mechanism 79 moves the hand 73.

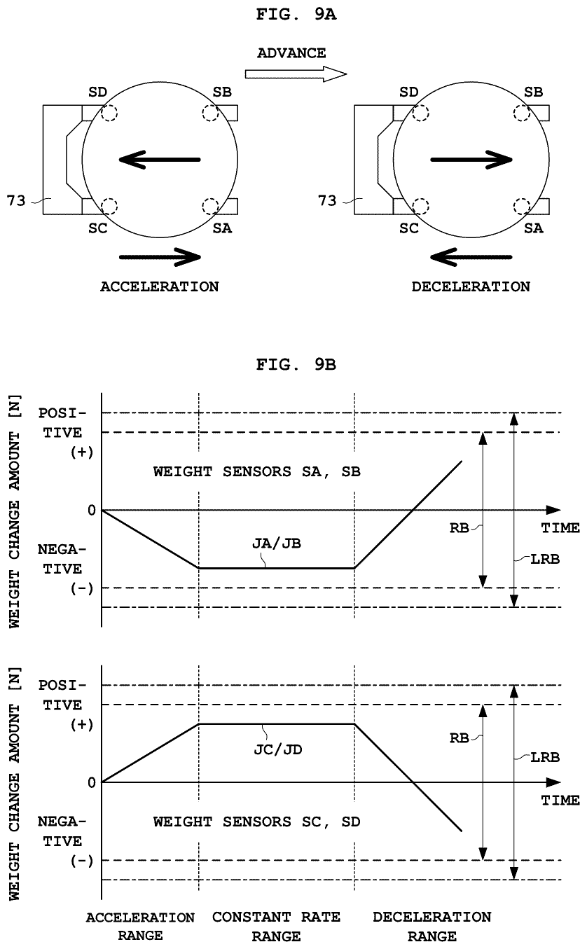

Reference is made to FIGS. 9A and 9B. It is assumed that the advancing and withdrawing mechanism 75 or the linear moving mechanism 79 moves the hand 73 forward. In this case, the liquid tends to move toward the weight sensors SC and SD in the acceleration range. Accordingly, weight values JC and JD measured by the weight sensors SC and SD, respectively, increase. In contrast to this, the weight values JA and JB measured by the weight sensors SA and SB, respectively, decrease. Moreover, the liquid tends to move toward the weight sensors SA and SB in a deceleration range. Accordingly, weight values JA and JB measured by the weight sensors SA and SB, respectively, increase. In contrast to this, the weight values JC and JD measured by weight sensors SC and SD, respectively decrease. Here in FIGS. 9A and 9B, the rotating mechanism 77 does not rotate the hand 73 around the vertical axis AX5.

As above, at least either movement or rotation of the hand 73 causes the liquid of the liquid film formed on the top face of the substrate W to move, and the weight change amount of the liquid can be monitored by the four weight sensors SA to SD.

Then, the robot controller 111 causes the hand 73 to support the substrate W with the liquid film formed on its top face to measure the weight of the liquid film with the four weight sensors SA to SD. The amount of liquid film (liquid volume) can be determined by the weight of the liquid film. Thereafter, the robot controller 111 obtains an acceleration/deceleration tolerance RA for moving the hand 73 in correspondence to the type of the substrate W and the weight of the measured liquid film. Then, the robot controller 111 causes the hand 73 to move at an acceleration/deceleration within the tolerance RA by the advancing and withdrawing mechanism 75 or the linear moving mechanism 79.

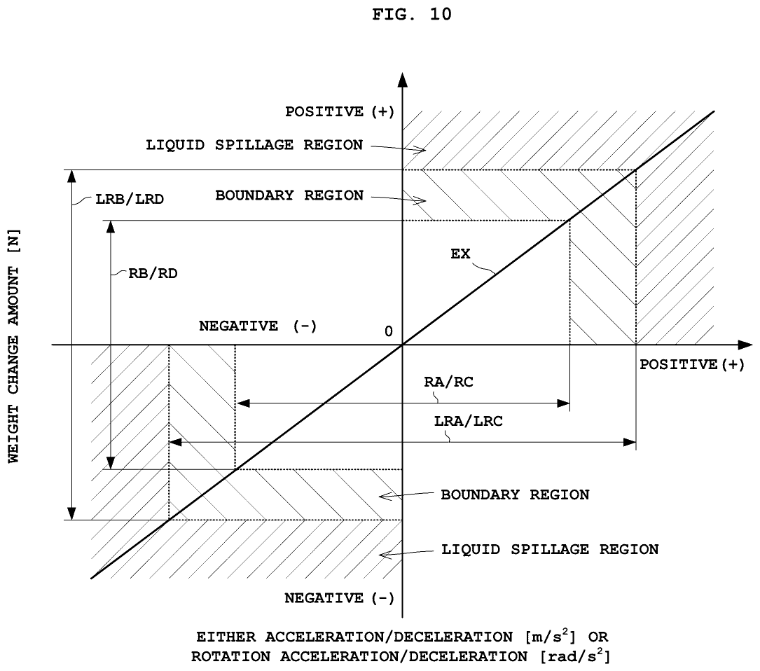

Reference is made to FIG. 10. The acceleration/deceleration tolerance RA is narrower than a limit range LRA of the acceleration/deceleration. The limit range LRA of the acceleration/deceleration is a limit range where the liquid does not spill from the substrate W due to movement of the liquid of the liquid film. If the acceleration/deceleration falls within the limit range LRA, no liquid spillage will occur unless it differs from an actual range. The limit range LRA of the acceleration/deceleration is set in advance through experiments and the like. For example, the limit range LRA is set by measuring the weight value (weight change amount) of the liquid, causing liquid spillages from the substrate W due to the movement of the liquid of the liquid film, with use of the four weight sensors SA to SD.

The limit range LRA is a range between a limit value of the acceleration (positive acceleration) (m/s²; meters per second squared) and a limit value of the deceleration (negative acceleration) (m/s²). Similarly, the tolerance RA of the acceleration/deceleration is the range between allowable values of the acceleration and the deceleration. The tolerance RA is also set in advance.

As shown in FIG. 10, the limit range LRA of the acceleration/deceleration corresponds to a limit range LRB of the weight change amount (N; newtons) of the liquid. If one of the four weight sensors SA to SD measures a weight change amount that falls outside the limit range LRB, the liquid will spill from the substrate W. Moreover, the acceleration/deceleration tolerance RA corresponds to the weight change amount tolerance RB of the liquid. In FIG. 10, the weight change amount is a change amount in weight relative to the weight of the liquid film at rest. Accordingly, a weight change amount of 0 (zero) indicates that the measured weight is unchanged from the weight at rest.

Moreover, the robot controller 111 obtains a rotation acceleration/deceleration tolerance RC for rotating the hand 73 in correspondence to the type of the substrate W and the measured weight of the liquid film. Then, the robot controller 111 rotates the hand 73 within the tolerance RC by the rotating mechanism 77.

The tolerance RC of the rotation acceleration/deceleration is narrower than a limit range LRC of the rotation acceleration/deceleration. The limit range LRC of the rotation acceleration/deceleration is a limit range where the liquid does not spill from the substrate W due to movement of the liquid of the liquid film. The limit range LRC of the rotation acceleration/deceleration is set in advance through experiments and the like. The limit range LRC is a range between limits of the rotational acceleration (positive rotational acceleration or positive angular acceleration) (rad/s²; radians per second squared) and the rotational deceleration (negative rotational acceleration or negative angular acceleration) (rad/s²). Similarly, the tolerance RC of the rotation acceleration/deceleration is the range between allowable values of the rotational acceleration and the rotational deceleration. The tolerance RC is also set in advance.

Moreover, the limit range LRC of the rotation acceleration/deceleration corresponds to a limit range LRD of the weight change amount of the liquid. Moreover, the rotation acceleration/deceleration tolerance RC corresponds to the weight change amount tolerance RD of the liquid. Here, as shown in FIG. 10, data showing a relationship between the rotation acceleration/deceleration and the weight change amount is prepared separately from data showing a relationship between the acceleration/deceleration and the weight change amount.

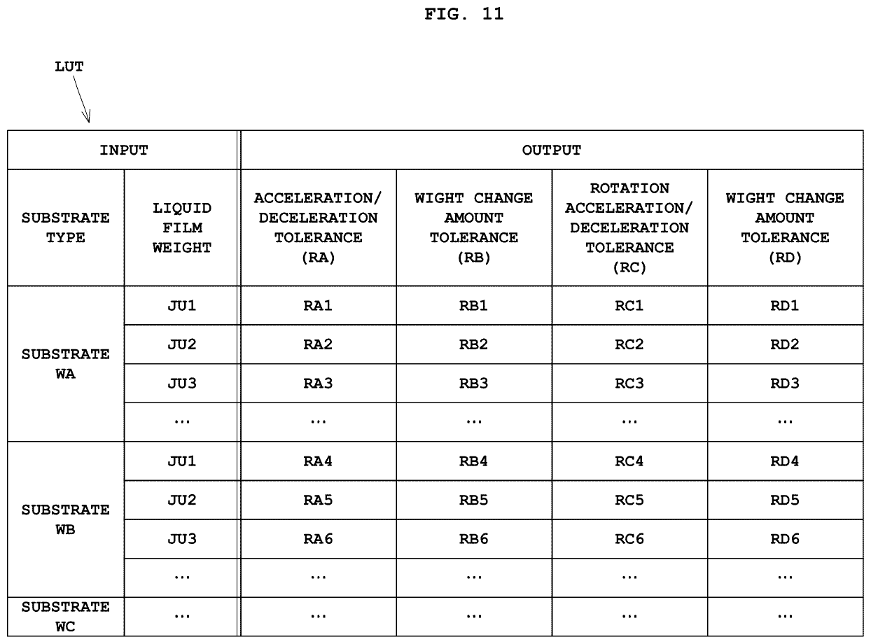

FIG. 11 is a view illustrating one example of a lookup table LUT. The lookup table LUT is stored in at least either the memory unit 113 or a memory unit 181 mentioned later. The robot controller 111 uses the lookup table LUT to obtain, for example, the tolerance RA of the acceleration/deceleration, the tolerance RC of the rotation acceleration/deceleration, and the tolerances RB, RD of the weight change amount corresponding to the type of a substrate W and the measured weight of the liquid film.

In FIG. 11, the type of the substrate W includes one selected from wettability of the substrate W, warpage of the substrate W (e.g., umbrella or bowl type), and a diameter of the substrate W (e.g., 300 mm). Wettability of a substrate W is, for example, whether the substrate W is hydrophilic or hydrophobic. For example, a substrate WA shown in FIG. 11 is a hydrophilic substrate and a substrate WB is a hydrophobic substrate. Moreover, the wettability is expressed by a contact angle. A weight of a liquid film is, for example, the sum of the weight values JA to JD measured by the four weight sensors SA to SD, respectively. For example, weights JU1, JU2, and JU3 are assigned to substrates WA, WB, and WC, respectively.

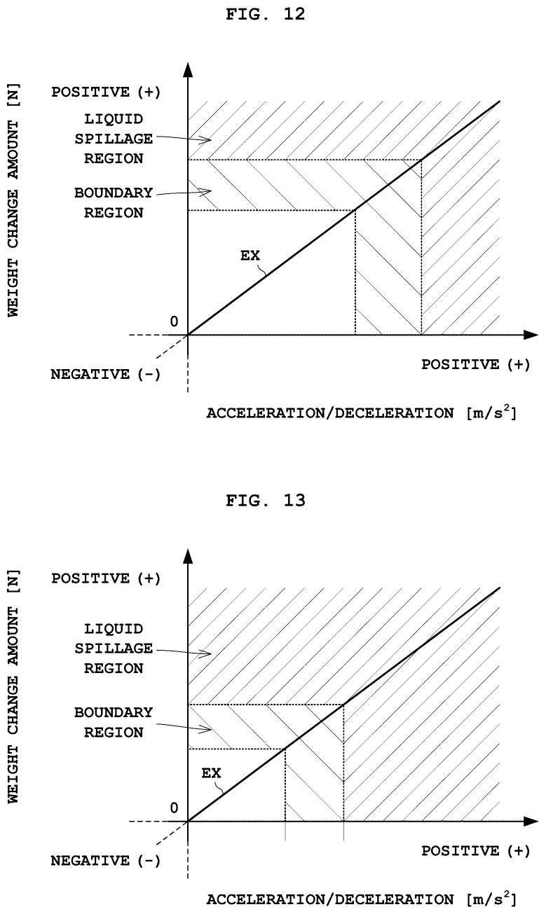

FIG. 12 is a view illustrating one example of a relationship between the acceleration/deceleration and the weight change amount of the liquid in a case of the hydrophilic substrate WA. In the case of the hydrophilic substrate WA, a relatively small amount of liquid (e.g., DIW) can cover the entire top face of the substrate W. Accordingly, no liquid spillage occurs until the weight change amount becomes large. FIG. 13 is a view illustrating one example of a relationship between the acceleration/deceleration and the weight change amount of the liquid in a case of the hydrophobic substrate WB. In the case of a hydrophobic substrate WB, a relatively large amount of liquid (e.g., DIW) is needed to cover the entire top face of the substrate W. Accordingly, liquid spillage occurs by a small weight change amount.

The tolerance RA of the acceleration/deceleration corresponds to the first range in the present invention. The tolerance RB of the weight change amount corresponds to the change amount range in the present invention. The tolerance RC of the rotation acceleration/deceleration corresponds to the second range in the present invention.

### 5. Single-Wafer Processing Device

Reference is made to FIG. 1. The single-wafer processing device 7 performs predetermined single-wafer processing of the substrates W received from the relay device 5 one by one.

The single-wafer processing device 7 includes an indexer block 121 and a treating block 123. The indexer block 121 includes, for example, four mount shelves 125 and an indexer robot IR. The four mount shelves 125 are arranged in the transverse direction Y. The four mount shelves 125 are arranged in front of the indexer robot IR. The mount shelves 125 each have a carrier C placed thereon.

The indexer robot IR transports a substrate W between the four carriers C placed on the four mount shelves 125, respectively, and a substrate platform PS2 mentioned later. The indexer robot IR includes a hand 127, an articulated arm 129, and a lifting and lowering board 131. The hand 127 holds one substrate W horizontally.

The articulated arm 129 moves the hand 127 horizontally and also changes an orientation of the hand 127. The articulated arm 129 has a distal end connected to the hand 127, and a proximal end connected to the lifting and lowering board 131. The lifting and lowering board 131 moves the hand 127 upward and downward via the articulated arm 129. The articulated arm 129 and the lifting and lowering board 131 each include, for example, an electric motor.

The treating block 123 is adjacent to the back of the indexer block 121. The treating block 123 includes a substrate transport region R4 and four towers TW1 to TW4, for example. The substrate transport region R4 extends rearward (front-back direction X) from the indexer block 121. The two towers TW1, TW2 are provided along the substrate transport region R4. The two towers TW3, TW4 are also provided along the substrate transport region R4. The two towers TW1, TW2 face the two towers TW3, TW4 across the substrate transport region R4.

The tower TW1 includes, for example, three single-wafer processing chambers SW1 arranged in the vertical direction Z. The tower TW3 includes, for example, two single-wafer processing chambers SW1 arranged in the vertical direction Z. In the tower TW3, the substrate platform PS1 of the relay device 5 is placed between the two single-wafer processing chambers SW1 arranged in the vertical direction Z. The two towers TW2, TW4 each include, for example, three single-wafer processing chambers SW2 arranged in the vertical direction Z. The eleven single-wafer processing chambers SW1, SW2 are each configured to perform treatment on the substrates W in horizontal postures one by one.

Note that the number of single-wafer processing chambers SW1, SW2 is not limited to eleven. Moreover, the number of single-wafer processing chambers SW1 is not limited to five, and only needs to be one or more. Moreover, the number of single-wafer processing chambers SW2 is not limited to six, and only needs to be one or more.

The single-wafer processing chambers SW1 each include a holding rotator 141 and a nozzle 143, for example. The holding rotator 141 includes a spin chuck configured to hold one substrate W in a horizontal posture, and an electric motor configured to rotate the spin chuck around a vertical axis passing through the center of the substrate W. The nozzle 143 supplies a treatment liquid to the top face of the substrate W held by the holding rotator 141. Pure water (e.g., DIW) or isopropyl alcohol (IPA) is used, for example, as the treatment liquid. The single-wafer processing chambers SW1 each perform cleaning treatment on the substrates W with pure water, and then form an IPA liquid film on top faces of the substrates W, for example.

The single-wafer processing chambers SW2 each perform dry treatment with supercritical fluid, for example. A carbon dioxide liquid is used as the fluid, for example. When the fluid is carbon dioxide, a supercritical state is obtained when the critical temperature is 31° C. and the critical pressure is 7.38 MPa. The dry treatment with a supercritical fluid prevents collapse of patterns on the substrate W.

The single-wafer processing chambers SW2 each include a chamber body (vessel) 145, a supporting tray 147, and a lid. The chamber body 145 includes a treating space provided therein, an opening through which substrates W enter the treating space, a supply port, and an exhaust port. The substrates W are accommodated into the treating space while being supported by the supporting tray 147. The lid closes the opening of the chamber body 145. For example, the single-wafer processing chambers SW2 each make a fluid into a supercritical state and supply the supercritical fluid from the supply port into the treating space in the chamber body 145. With the supercritical fluid supplied into the treating space, dry treatment is performed on one substrate W.

The substrate transport region R4 contains a center robot CR1 and a substrate platform PS2 (shelf). The substrate platform PS2 is located between the indexer robot IR and the center robot CR1. The substrate platform PS2 has one or more substrates W placed thereon.

The center robot CR1, for example, transports one substrate W in a horizontal posture between the substrate platforms PS1, PS2 and the eleven single-wafer processing chambers SW1, SW2. The center robot CR1 includes, for example, two hands 151, 152, an advancing and withdrawing mechanism 153, a lifting and rotating mechanism 155, and a linear moving mechanism 157. The two hands 151, 152 each hold one substrate W in a horizontal posture. The hand 151 supports a substrate W with a liquid film formed on its top face. The hand 152 supports a substrate W subjected to the dry treatment. The hand 152 is positioned higher than the hand 151. This prevents a spilled liquid from adhering to the top face of the substrate W supported by the hand 152 even if the liquid spills from the substrate W held by the hand 151.

The advancing and withdrawing mechanism 153 moves the two hands 151, 152 forward and backward individually. The lifting and rotating mechanism 155 moves the two hands 151, 152 and the advancing and withdrawing mechanism 153 upward and downward. Moreover, the lifting and rotating mechanism 155 rotates the two hands 151, 152 and the advancing and withdrawing mechanism 153 around a vertical axis AX7 in order to change the orientation of the two hands 151, 152. The advancing and withdrawing mechanism 153 and the lifting and rotating mechanism 155 each include an electric motor, for example. The linear moving mechanism 157 moves the two hands 151, 152, the advancing and withdrawing mechanism 153 and the lifting and rotating mechanism 155 in the front-back direction X. The linear moving mechanism 157 includes a guide rail, a slider, and an electric motor, for example.

The treating block 123 further includes two substrate transporting robot CR2, CR3. The first substrate transporting robot CR2 is provided between the two towers TW1, TW2. Moreover, the second substrate transporting robot CR3 is provided between the two towers TW3, TW4. The substrate transporting robots CR2. CR3 each transport a substrate W, on the top face of which the liquid film (e.g., IPA film) is formed, from the single-wafer processing chamber SW1 to the single-wafer processing chamber SW2. Similarly to the center robot CR1, the substrate transporting robots CR2, CR3 each include the hand 151, the advancing and withdrawing mechanism 153, and the lifting and rotating mechanism 155. Here, the lifting and rotating mechanism 155 of each of the substrate transporting robots CR2, CR3 rotates the hand 151 and the like around a vertical axis AX8.

### 6. Controller

The substrate treating system 1 includes a main controller 180 and a memory unit 181 (not shown). The main controller 180 controls each component of the substrate treating system 1. The main controller 180 includes one or more processors like a central processing unit (CPU). The memory unit 181 includes, for example, at least one of a read-only memory (ROM), a random-access memory (RAM), and a hard disk. The memory unit 181 stores computer programs necessary for controlling each component of the substrate treating system 1. Here, the robot controller 111 or the main controller 180 corresponds to the controller in the present invention. The memory unit 113 or the memory unit 181 corresponds to the memory in the present invention.

### 7. Operation of Substrate Treating System

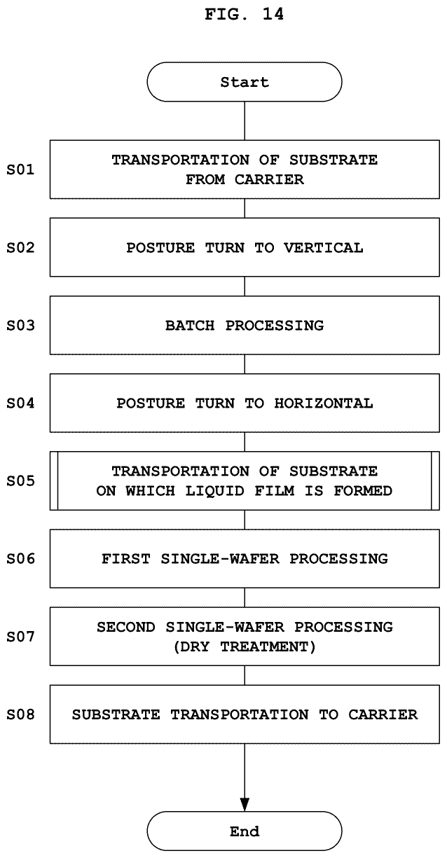

The following describes operation of the substrate treating system 1 with reference to a flowchart in FIG. 14.

[Step S01] Transportation of Substrate from Carrier

Reference is made to FIG. 1. An external transport robot, not shown, transports a carrier C to one of the load ports 9. The carrier transport robot 13 of the stocker 2 transports the carrier C from the load port 9 to the mount shelf 17. The carrier C accommodates, for example, twenty-five substrates W before treatment.

Thereafter, the substrate handling mechanism HTR of the batch processing device 3 takes the twenty-five substrates W in horizontal postures from the carrier C placed on the mount shelf 17, and transports the twenty-five substrates W to the posture turning unit 31. The carrier transport robot 13 then transports the carrier C, which has been emptied after the twenty-five substrates W have been taken, from the mount shelf 17 to the load port 9. The external transport robot transports the empty carrier C from the load port 9 to one of the four mount shelves 125.

### [Step S02] Posture Turn to Vertical

Thereafter, the posture turning unit 31 turns a posture of the twenty-five substrates W from horizontal to vertical (see FIGS. 2A, 2B). The pusher mechanism 33 receives the twenty-five substrates W in vertical postures from the posture turning unit 31, and transports the twenty-five substrates W to the substrate delivery position PP (see FIG. 2C).

### [Step S03] Batch Processing

Reference is made to FIG. 1. The first batch transport robot WTR1 receives the twenty-five substrates W in vertical postures from the pusher mechanism 33, and transports the twenty-five substrates W to one of the two chemical liquid process tanks BT1, BT2. For example, the lifter LF1 receives the twenty-five substrates W in vertical postures from the first batch transport robot WTR1 above the chemical liquid process tank BT1, and immerses the twenty-five substrates W in a phosphoric acid solution (chemical liquid) stored in the chemical liquid process tank BT1. Accordingly, a chemical liquid treatment is performed on the twenty-five substrates W collectively. Here, the same chemical liquid treatment is performed when the lifter LF2 receives twenty-five substrates W from the first batch transport robot WTR1.

The lifter LF1 then pulls the twenty-five substrates W out of the phosphoric acid solution. The first batch transport robot WTR1 receives the twenty-five substrates W from the lifter LF1, and transports them to one of the two cleaning process tanks BT3, BT4. For example, the lifter LF3 receives the twenty-five substrates W from the first batch transport robot WTR1 above the cleaning process tank BT3, and immerses the twenty-five substrates W in pure water (e.g., DIW) stored in the cleaning process tank BT3. This removes the phosphoric acid solution from each substrate W. Moreover, a cleaning treatment is performed on the twenty-five substrates W collectively. Here, the same cleaning treatment is performed when the lifter LF4 receives twenty-five substrates W from the first batch transport robot WTR1.

The lifter LF3 then pulls the twenty-five substrates W out of the pure water. The first batch transport robot WTR1 receives the twenty-five substrates W from the lifter LF3, and transports the twenty-five substrates W to the posture turning region R2 of the relay device 5. The substrates W are each wet.

### [Step S04] Posture Turn to Horizontal

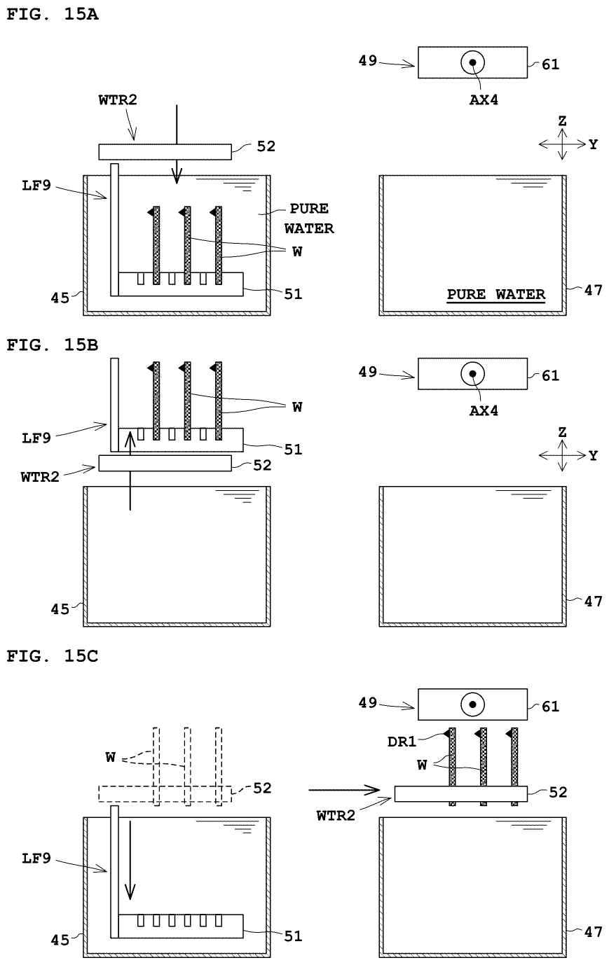

Thereafter, the stand-by lifter LF9 receives the twenty-five substrates W in vertical postures from the first batch transport robot WTR1 above the stand-by tank 45. Then, as shown in FIG. 15A, the stand-by lifter LF9 immerses the twenty-five substrates W in pure water (e.g., DIW) stored in the stand-by tank 45. At this time, the chuck 52 of the second batch transport robot WTR2 is open.

Reference is made to FIG. 15B. The stand-by lifter LF9 then lifts the twenty-five substrates W to a position higher than the chuck 52. Accordingly, the twenty-five substrates W are pulled out of the pure water in the stand-by tank 45. Thereafter, the second batch transport robot WTR2 brings the chuck 52 into a closed state. This makes the chuck 52 ready to hold the twenty-five substrates W.

Reference is made to FIG. 15C. The stand-by lifter LF9 then lowers the twenty-five substrates W. This allows the chuck 52 to receive the twenty-five substrates W from the stand-by lifter LF9. Thereafter, the second batch transport robot WTR2 moves the chuck 52, holding the twenty-five substrates W, from above the stand-by tank 45 to above the posture turning tank 47 (i.e., below the rotary chuck 61 of the posture turning unit 49). At this time, the rotary chuck 61 is open.

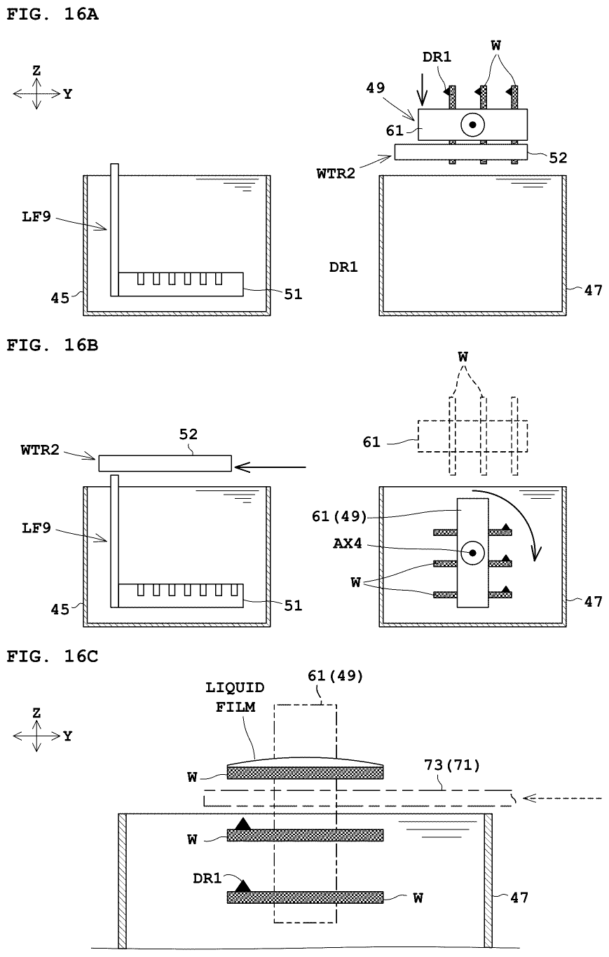

Reference is made to FIG. 16A. The posture turning unit 49 then lowers the rotary chuck 61, thereby positioning the twenty-five substrates W in vertical postures between the one-paired chuck members 65, 66. Thereafter, the posture turning unit 49 brings the rotary chuck 61 into a closed state. Accordingly, the rotary chuck 61 holds the twenty-five substrates W that the chuck 52 holds.

Reference is made to FIG. 16B. Thereafter, the second batch transport robot WTR2 brings the chuck 52 into an opened state, thereby releasing the twenty-five substrates W. The second batch transport robot WTR2 then moves the chuck 52 in the opened state from above the posture turning tank 47 to above the stand-by tank 45.

The posture turning unit 49 then lowers the rotary chuck 61 that holds the twenty-five substrates W in the vertical postures. The twenty-five substrates W are then immersed in the pure water (e.g., DIW) stored in the posture turning tank 47. Thereafter, the posture turning unit 49 turns postures of the twenty-five substrates W from vertical to horizontal in the pure water by rotating the rotary chuck 61 by 90 degrees around the horizontal axis AX4. Device faces of the substrates W in the horizontal postures are each directed upward.

Reference is made to FIG. 16C. The posture turning unit 49 then lifts the rotary chuck 61 to pull the substrate W in the highest position out of the pure water, for example. At this time, the substrate W in the highest position is pulled out of the pure water while scooping up the pure water with the top face thereof. As a result, a liquid film (a pure water film) is formed on the top face of the substrate W.

[Step S05] Transportation of Substrate on which Liquid Film is Formed

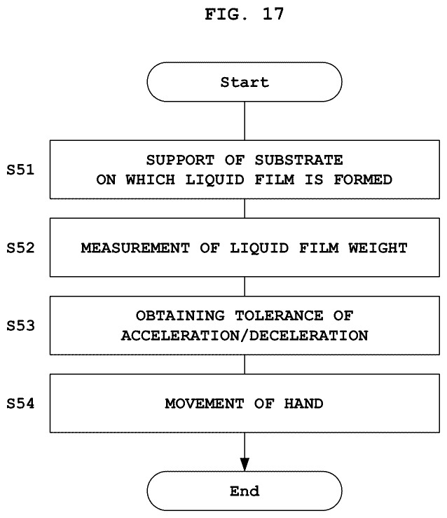

In the relay region R3 of the relay device 5, the substrate transporting robot 71 transports the substrate W with a liquid film formed on its top face. FIG. 17 is a flow chart showing detailed transportation of the substrate W in the step S05.

[Step S51] Support of Substrate on which Liquid Film is Formed

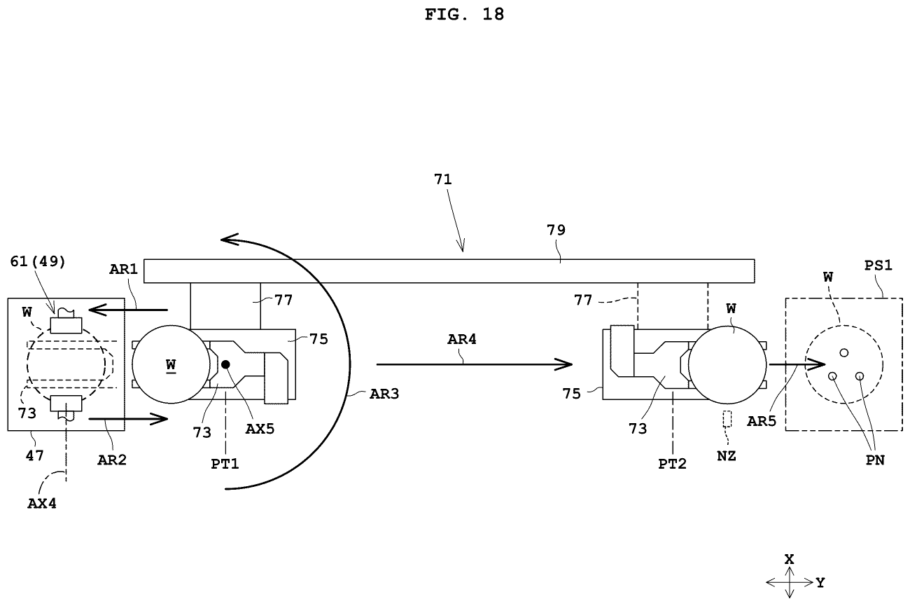

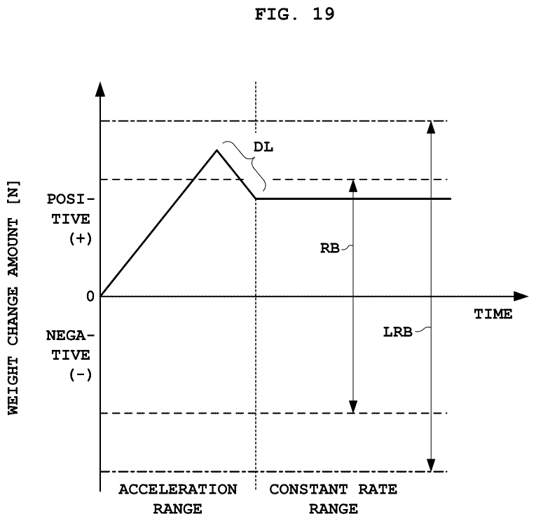

Reference is made to FIGS. 1 and 18. First, the linear moving mechanism 79 of the substrate transporting robot 71 moves the hand 73 and the like, which do not support the substrate W, to a position PT1 adjacent to the posture turning unit 49. Here, the distal end of the hand 73, i.e. hand 73, faces the posture turning unit 49. Thereafter, the advancing and withdrawing mechanism 75 moves the hand 73 forward (arrow AR1 in FIG. 18). This causes the hand 73 to access the posture turning unit 49, and also to move below the substrate W at the highest position, as shown by chain double-dashed line in FIG. 16C. The posture turning unit 49 lowers the rotary chuck 61 slightly. Accordingly, the substrate W at the highest position is placed on the upper surfaces of the four contacting parts 97A to 97D of the hand 73. In the following description, the substrate W at the highest position is referred to as a “substrate W”.

As such, the substrate transporting robot 71 supports the substrate W, on the top face of which the liquid film (pure water film) is formed, by the hand 73. In this case, the substrate W is not supported by the rotary chuck 61, but only by the hand 73.

### [Step S52] Measurement of Liquid Film Weight

The hand 73 is provided with four weight sensors SA to SD corresponding to the four contacting parts 97A to 97D. A weight of the liquid film is measured by the four weight sensors SA to SD. Four weight values JA to JD output from the four weight sensors SA to SD are sent to the robot controller 111. The robot controller 111 calculates the weight of the liquid film by summing the four weight values JA to JD, for example.

In detail, the four weight values JA to JD, respectively, measured by the four weight sensors SA to SD include the weight of the liquid film and the weight of the substrate W. Therefore, a weight of a dummy substrate W, which is equivalent (in shape and material) to the substrate W to be transported by the hand 73, is first measured in advance, so that the weight of the substrate W is stored in at least either the memory unit 113 or the memory unit 181, for example. Then, the weight of the dummy substrate is subtracted from the weight of the substrate W on which the liquid film is formed. This gives the weight of the liquid film.

### [Step S53] Obtaining Tolerance of Acceleration/Deceleration

The robot controller 111 obtains a tolerance RA of the acceleration/deceleration and a tolerance/deceleration RC of the rotational acceleration and the like for movement of the hand 73 in correspondence to the measured weight of the liquid film and the type of the substrate W, as shown in FIG. 11. In the lookup table LUT of FIG. 11, for example, an acceleration/deceleration tolerance RA6 and a rotational acceleration/deceleration tolerance RC6 and the like are obtained from a weight JU3 of a liquid film and a substrate WB.

### [Step S54] Movement of Hand

The robot controller 111 moves the hand 73 at an acceleration/deceleration within the tolerance RA by the advancing and withdrawing mechanism 75 or the linear moving mechanism 79. Also, the robot controller 111 rotates the hand 73 within a rotation acceleration/deceleration tolerance RC by the rotating mechanism 77. The following describes a specific example of operation.

Reference is made to FIG. 18. The current state is that the hand 73 accesses the posture turning unit 49 and also supports the substrate W on which the liquid film is formed. Accordingly, the advancing and withdrawing mechanism 75 then withdraws the hand 73 supporting the substrate W (arrow AR2 in FIG. 18). Here, the advancing and withdrawing mechanism 75 moves the hand 73 backward at an acceleration/deceleration withing the tolerance RA. This can prevent the liquid from spilling from the substrate W during backward movement of the hand 73. Moreover, the acceleration/deceleration tolerance RA corresponds to the weight change amount tolerance RB. Therefore, in FIG. 7B, detection waveforms of the four weight sensors SA to SD fall within the tolerance RB.

After the hand 73 is withdrawn, the rotating mechanism 77 rotates the hand 73 supporting the substrate W by 180 degrees counterclockwise around the vertical axis AX5 (arrow AR3 in FIG. 18). Accordingly, the orientation of the hand 73 toward the posture turning unit 49 is changed to the substrate platform PS1. Here, the rotating mechanism 77 rotates the hand 73 by 180 degrees at a rotation acceleration/deceleration within the tolerance RC. This can prevent the liquid from spilling from the substrate W during rotation (orientation change) of the hand 73. Moreover, the rotation acceleration/deceleration tolerance RC corresponds to the weight change amount tolerance RD. Therefore, in FIG. 8B, detection waveforms of the four weight sensors SA to SD fall within the tolerance RD.

After changing the orientation of the hand 73 toward the substrate platform PS1, the linear moving mechanism 79 moves the hand 73 supporting the substrate W, the advancing and withdrawing mechanism 75, and the rotating mechanism 77 from the position PT1 adjacent to the posture turning unit 49 to the position PT2 adjacent to the substrate platform PS1 (arrow AR4 in FIG. 18). Here, similarly, the linear moving mechanism 79 moves the hand 73 and the like at an acceleration/deceleration within the tolerance RA. Here in FIG. 9B, detection waveforms of the four weight sensors SA to SD fall within the weight change amount tolerance RB.

After the hand 73 and the like are moved to the position PT2, the advancing and withdrawing mechanism 75 moves the hand 73, supporting substrate W, forward (arrow AR5 in FIG. 18) above the substrate platform PS1. Here, the advancing and withdrawing mechanism 75 moves the hand 73 forward at an acceleration/deceleration within the tolerance RA. Here in FIG. 9B, detection waveforms of the four weight sensors SA to SD fall within the weight change amount tolerance RB.

After the hand 73 is moved forward above the substrate platform PS1, three lift pins PN (see FIG. 18) of the substrate platform PS1 are lifted by an electric motor. Accordingly, the three lift pins PN receive the substrate W from the hand 73 while supporting the lower face of the substrate W on which the liquid film is formed. The substrate transporting robot 71 then withdraws the hand 73 that does not support the substrate W. Thereafter, the substrate transporting robot 71 transports the remaining twenty-four substrates W to the substrate platform PS1 one by one. Here, a liquid film is formed on each top face of the substrates W to be transported.

### [Step S06] First Single-Wafer Processing

Reference is made to FIG. 1. The center robot CR1 of the single-wafer processing device 7 uses the hand 151 to receive a substrate W, with a liquid film formed thereon, from the substrate platform PS1, and transports the substrate W to one of the five single-wafer processing chambers SW1 in the two towers TW1, TW3. A holding rotator 141 of each of the single-wafer processing chambers SW1 holds and rotates the substrate W in the horizontal posture with the device surface directed upward. Moreover, each of the single-wafer processing chambers SW1 supplies pure water from a nozzle 143 to the device surface (top face) of the substrate W to be rotated, and then supplies IPA from the nozzle 143 to the device surface. This replaces the pure water on the top face of the substrate W with IPA.

### [Step S07] Second Single-Wafer Processing

The first substrate transporting robot CR2 uses hand 151 to receive a substrate W, with a liquid film (IPA film) formed thereon, from one of the three single-wafer processing chambers SW1 in the tower TW1. Thereafter, the first substrate transporting robot CR2 transports the substrate W to one of the three single-wafer processing chambers SW2 in the tower TW2.

The second substrate transporting robot CR3 uses hand 151 to receive a substrate W, with a liquid film (IPA film) formed thereon, from one of the two single-wafer processing chambers SW1 in the tower TW3. Thereafter, the second substrate transporting robot CR3 transports the substrate W to one of the three single-wafer processing chambers SW2 in the tower TW4.

The single-wafer processing chambers SW2 each perform dry treatment on one substrate W with carbon dioxide under a supercritical state (supercritical fluid). Such dry treatment with the supercritical fluid prevents pattern collapse of the device faces of the substrates W.

### [Step S08] Substrate Transportation to Carrier

The center robot CR1 uses the hand 152 to receive one substrate W, subjected to the dry treatment, from one of the six single-wafer processing chambers SW2, and to transport the one substrate W to the substrate platform PS2. Twenty-five substrates W, subjected to the dry treatment, are transported in turn to the substrate platform PS2.

The indexer robot IR uses the hand 127 to transport the substrates W placed on the substrate platform PS2 to a carrier C placed on the mount shelf 125. When the twenty-five substrates W subjected to the dry treatment are transported to the carrier C, an external transport robot, not shown, transports the carrier C from the mount shelf 125 to a next destination.

With the present embodiment, the tolerance RA of the acceleration/deceleration for moving the hand 73 is obtained in correspondence to the type of the substrate W and the weight of the liquid film (state of the liquid film). The hand 73 is moved at an acceleration/deceleration within the tolerance RA. This prevents a liquid from spilling from the top face of the substrate W during transportation. Since the tolerance RA of the acceleration/deceleration is a range where the wettability of the substrate W is taken into account, the accuracy of the tolerance RA of the acceleration/deceleration can be enhanced. Moreover, the lookup table LUT table makes it easy to obtain the acceleration/deceleration tolerance RA.

The substrate transporting robot includes the four weight sensors SA to SD as the sensors that detect the state of a liquid film. The four weight sensors SA to SD are provided on the hand 73. Accordingly, the robot controller 111 can obtain the acceleration/deceleration tolerance RA by considering the weight of the liquid film actually measured by the four weight sensors SA to SD. In addition, the four weight sensors SA to SD are relatively small and relatively inexpensive. Accordingly, the hand 73 is less likely to be large even if the four weight sensors SA to SD are provided on the hand 73. Therefore, space or cost issues are less likely to arise.

With the present embodiment, the tolerance RC of the rotation acceleration/deceleration for rotating the hand 73 is obtained in correspondence to the type of the substrate W and the weight of the liquid film (state of the liquid film). The hand 73 is rotated at a rotation acceleration/deceleration within the tolerance RC. This prevents a liquid from spilling from the top face of the substrate W during transportation (especially, rotation).

### Second Embodiment

The following describes a second embodiment of the present invention with reference to the drawings. Here, the description common to that of the first embodiment is to be omitted.

In the first embodiment, during the horizontal movement of the hand 73, the substrate transporting robot 71 takes no particular action even if the weight change amount of the liquid measured by the weight sensor SA may exceed the tolerance RB, for example. In this regard, in the second embodiment, if the weight change amount of the liquid exceeds the tolerance RB, the acceleration/deceleration of the hand 73 during transportation (movement) is controlled (adjusted) so that the weight change amount of the liquid falls within the tolerance RB.

The robot controller 111 monitors the four weight change amounts of the liquid moving on the top face of the substrate W at the measurement positions of the weight sensors SA to SD based on the four weight values JA to JD determined by the four weight sensors SA to SD while the hand 73 moves. Then, when any of the four weight change amounts deviates from the tolerance RB of the weight change amount corresponding to the tolerance RA of the acceleration/deceleration, the robot controller 111 reduces an absolute value of the acceleration/deceleration of the hand 73 so that the weight change amount falls within the tolerance RB.

For example, it is assumed that there is a case in the acceleration range in FIG. 19 where the liquid accumulates on a side adjacent to the weight sensor SA and the weight change amount of the weight value JA measured by the weight sensor SA exceeds the tolerance RB. In this case, the acceleration (absolute value) is reduced so that the weight change amount of the weight value JA falls within the tolerance RB (numeral DL in FIG. 19). This keeps the weight change amount of the weight value JA within the tolerance RB and reduces a possibility of liquid spillage.

Similarly, the robot controller 111 monitors the four weight change amounts of the liquid moving on the top face of the substrate W at the measurement positions of the weight sensors SA to SD based on the four weight values JA to JD determined by the four weight sensors SA to SD while the hand 73 rotates around the vertical axis AX5. Then, when any of the four weight change amounts deviates from the tolerance RD of the weight change amount corresponding to the tolerance RC of the rotation acceleration/deceleration, the robot controller 111 reduces an absolute value of the rotation acceleration/deceleration so that the weight change amount falls within the tolerance RD.

The following describes effects of the present embodiment. If the obtained acceleration/deceleration falls within the tolerance RA, no liquid spillage will occur. On the other hand, a relationship between the obtained tolerance RA and the weight change amount tolerance RB may change due to some factors. In this case, a possibility of liquid spillage increases. Even in such a case, the weight change amount is adjusted to fall within the tolerance RB if the weight change amount is out of the weight change amount tolerance RB as a threshold. This can prevent liquid spillage.

The present invention is not limited to the foregoing examples, but may be modified as follows.

(1) In each of the embodiments described above, at least one of the center robot CR1 and the two substrate transporting robots CR2, CR3 may be configured in the same manner as the substrate transporting robot 71 that prevents liquid spillage from the substrate W. In this case, at least one of the center robot CR1 and two substrate transporting robots CR2, CR3, which are configured in the same manner as the substrate transporting robot 71, corresponds to the substrate transporting robot in the present invention.

In the present modification, for example, the hand 151 includes four weight sensors SA to SD like the hand 73 shown in FIG. 6. The main controller 180 obtains a tolerance RA of the acceleration/deceleration for moving the hand 151 in correspondence to the type of the substrate W and the measured weight of the liquid film. Thereafter, the main controller 180 moves the hand 151 at an acceleration/deceleration within the tolerance RA by the advancing and withdrawing mechanism 153 or the linear moving mechanism 157, for example.

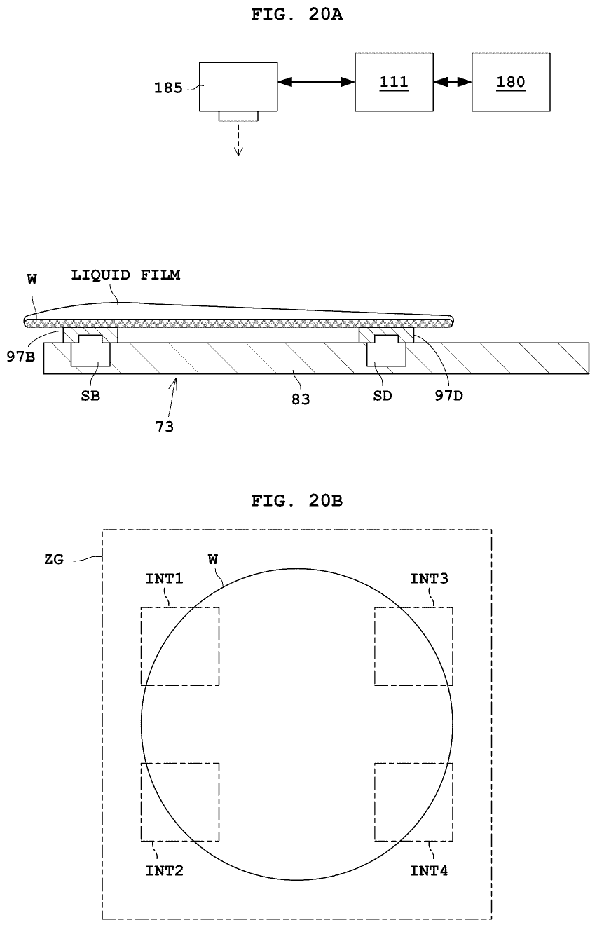

(2) In each of the embodiments and the modification (1) described above, the substrate transporting robot 71 includes the four weight sensors SA to SD for measuring a weight of a liquid film as the sensor that detects the state of the liquid film. In this regard, the substrate transporting robot 71 may include a camera 185 as a sensor instead of the four weight sensors SA to SD. As shown in FIG. 20A, the camera 185 images the entire liquid film formed on the top face of the substrate W supported by the hand 73 from above the substrate W, for example. Accordingly, an overall image ZG of the liquid film is obtained, as shown in FIG. 20B. The overall image ZG of the liquid film is sent to the robot controller 111.

The robot controller 111 may obtain an equivalent value corresponding to the weight of the liquid film or the amount of liquid film (liquid volume) based on pixel values indicating shading of the liquid film as mapped on the overall image ZG. Then, the robot controller 111 may obtain, for example, the tolerance RA of the acceleration/deceleration and the like for moving the hand 73 in correspondence to the type of substrate W and the acquired equivalent value.

Moreover, the camera 185 may be moved along with the hand 73. This allows the robot controller 111 to monitor an amount of change of the four equivalent values in the four regions of interest INT1, INT2, INT3, INT4 (see FIG. 20B) of the overall image ZG based on the overall image ZG captured by the camera 185 during movement of the hand 73. Moreover, when any of the amount of change of the four equivalent values deviates from change range corresponding the to the amount acceleration/deceleration tolerance RA, the robot controller 111 reduces an absolute value of the acceleration/deceleration of the hand 73 so as to fall within the change amount range.

(3) In each of the embodiments and the modifications described above, the substrate transporting robot 71 includes the weight sensors SA to SD for measuring a weight of a liquid film as the sensor that detects the state of the liquid film. In this regard, the substrate transporting robot 71 may include a film thickness meter 187 as a sensor instead of the four weight sensors SA to SD.

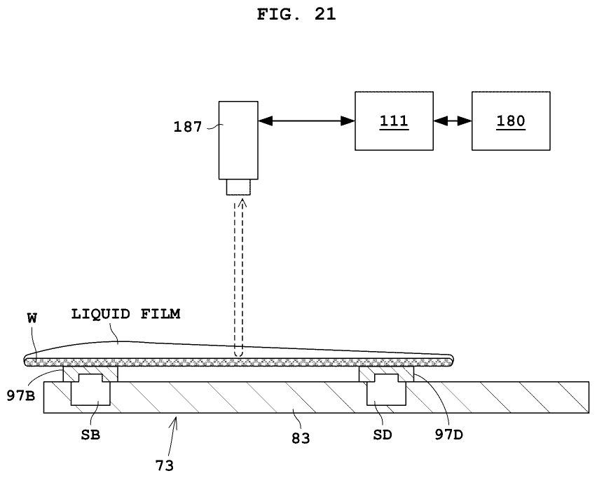

For example, a non-contact type film thickness meter that uses laser light is used as the film thickness meter 187. As shown in FIG. 21, the film thickness meter 187 measures a film thickness of a liquid film, formed on the top face of the substrate W supported by the hand 73, at a determined position from above the substrate W, for example. The film thickness is sent to the robot controller 111. The robot controller 111 obtains a range of the acceleration/deceleration for moving the hand 73 in correspondence to the measured liquid film thickness and the type of the substrate W.

(4) In each of the embodiments and the modifications described above, the robot controller 111 uses the lookup table LUT shown in FIG. 11 to obtain the acceleration/deceleration tolerance RA for moving the hand 73 in correspondence to the type of the substrate W and the measured weight of the liquid film. In this regard, the robot controller 111 may obtain the acceleration/deceleration tolerance RA and the rotation acceleration/deceleration tolerance RC without using the lookup table LUT.

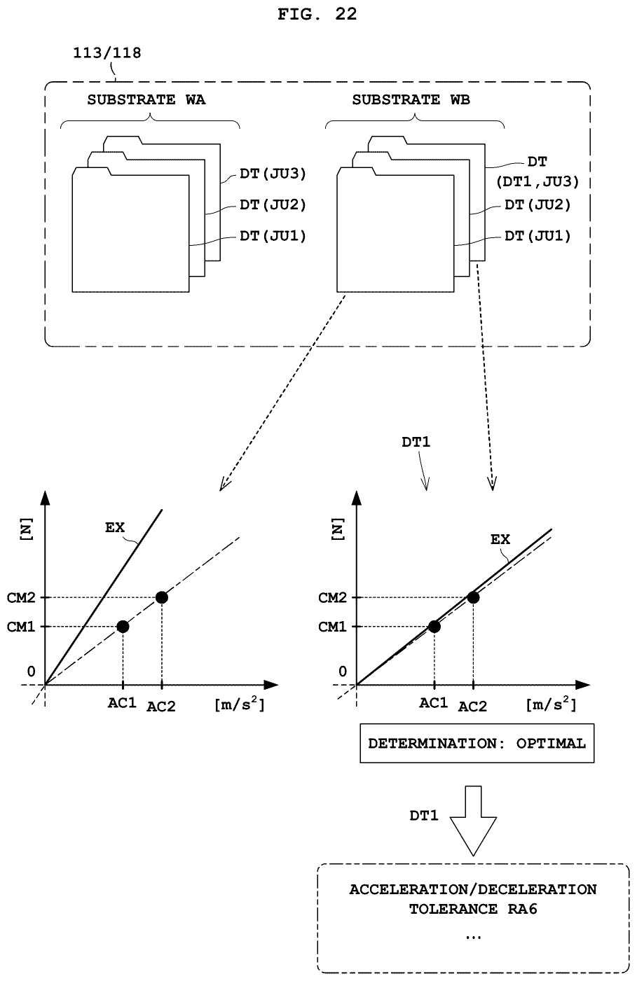

For example, the robot controller 111 obtains the acceleration/deceleration tolerance RA and the like as under. First, as shown in FIG. 22, the memory unit 113 or the memory unit 181 stores a plurality of pieces of relational data DT, each different for a different combination of the type of the substrate W and the weight of the liquid film. Each pieces of relational data DT includes a relation EX (relational expression) between the weight change amount of the liquid film (an amount of change in the state of the liquid film) and the acceleration/deceleration, an acceleration/deceleration tolerance RA in the relation EX, and a weight change amount tolerance RB.

The robot controller 111 supports the substrate W, on which the liquid film is formed, with the hand 73. Thereafter, the robot controller 111 measures the four weight values JA to JD with the four weight sensors SA to SD. Here, the robot controller 111 may obtain the weight of the liquid film based on the four measured weight values JA to JD. Moreover, the robot controller 111 measures the four weight change amounts CM1 of the liquid films by the four weight sensors SA to SD when the hand 73 is moved at the preset acceleration/deceleration AC1 by the advancing and withdrawing mechanism 75 or the linear moving mechanism 79.

Then, the robot controller 111 compares the preset acceleration/deceleration AC1 and the measured weight change amounts CM1 of the liquid film against the relation EX of each of the plurality of pieces of relational data DT. In this manner, the robot controller 111 extracts one piece of the relational data DT1 with the optimal relation EX from the plurality of pieces of relational data DT. The robot controller 111 also obtains the tolerance RA of the acceleration/deceleration and the tolerance RB of the weight change amount that the one piece of the relational data DT1 has. Here, the rotation acceleration/deceleration tolerance RC of the weight change amount tolerance RD are obtained similarly.

With the present modification, even if conditions for the type of the substrate W is insufficiently provided, for example, the optimal (approximate) relational data DT can be obtained from the plurality of pieces of relational data DT already owned, and the tolerance RA of the acceleration/deceleration and the tolerance RB of the weight change amount owned by said relational data DT can be obtained. If plural weight change amounts CM1, CM2 are obtained by plural accelerations/decelerations AC1, AC2, accuracy of the matching can be enhanced.

(4) In each of the embodiments and the modifications described above, the substrate transporting robot 71 cannot move the hand 73 upward and downward. In this regard, the substrate transporting robot 71 may be configured to move the hand 73 upward and downward.

(5) In each of the embodiments and the modifications described above, the hand 73 is advanced and withdrawn by the screw shaft 87 and the guide rail 89 of the advancing and withdrawing mechanism 75. In this regard, the hand 73 may be advanced and withdrawn by an articulated arm instead of the advancing and withdrawing mechanism 75.

(6) In each of the embodiments and the modifications described above, the advancing and withdrawing mechanism 75 moves the hand 73 when the linear moving mechanism 79 does not move the hand 73. In this regard, the advancing and withdrawing mechanism 75 may move the hand 73 when the linear moving mechanism 79 moves the hand 73.

(7) In each of the embodiments and the modifications described above, the rotating mechanism 77 rotates the hand 73 around the vertical axis AX5 when the advancing and withdrawing mechanism 75 nor the linear moving mechanism 79 do not move the hand 73. In this regard, the rotating mechanism 77 may rotate the hand 73 around the vertical axis AX5 when at least either the advancing and withdrawing mechanism 75 or the linear moving mechanism 79 moves the hand 73.

(8) In each of the embodiments and the modifications described above, the acceleration/deceleration tolerance RA and the rotation acceleration/deceleration tolerance RC are ranges corresponding to the type of the substrate W and the weight of the liquid film (liquid film state). In this regard, the tolerances RA, RC may correspond to the type of the liquid, the temperature of the liquid, the type of the substrate W, and the weight of the liquid film. Here, the liquid is a liquid of the liquid film formed on the top face of the substrate W.

(9) In each of the embodiments and the modifications described above, the liquid film is formed on the top face of the substrate W when the substrate in a horizontal posture is pulled up from the pure water in the posture turning unit 49 in FIG. 16C. In this regard, the liquid film may be formed on the top face of the substrate W by supplying pure water in a columnar or atomized form to the top face of the substrate W from a nozzle.

For example, the relay region R3 may contain a nozzle NZ shown in dotted lines in FIG. 18. For example, it is assumed that treatment of the single-wafer processing device 7 stops, and the substrate W supported by the hand 73 moved to the position PT2 is unable to be transported. In this case, the liquid film on the top face of the substrate W may be volatilized and reduced. Accordingly, supplying pure water from the nozzle NZ to the top face of substrate W can prevent the substrate W from drying out.

(10) In each of the embodiments and the modifications described above, the hand 73 includes the four weight sensors SA to SD. With this, a weight is measured at four points of the hand 73. In this regard, the number of weight sensors is not limited to four. In other words, the hand 73 may include at least one weight sensor provided in the hand body 83. Moreover, one weight sensor may be located in any of the four contacting parts 97A to 97D, for example. Moreover, two weight sensors may be provided in any two of the four contacting parts 97A to 97D, for example.

(11) In each of the embodiments and the modifications described above, the robot controller 111 obtains the acceleration/deceleration tolerance RA and the rotation acceleration/deceleration tolerance RC in correspondence to the type of the substrate W and the weight of the liquid film measured by the four weight sensors SA to SD. In this regard, if the weight of the liquid film is known to some extent by the amount of liquid supplied from the nozzle to the top face of the substrate W (milliliters), for example, the tolerance RA and the like do not need to reflect the weight of the liquid film measured by the four weight sensors SA to SD. In such a case, for example, the robot controller 111 obtains from the memory unit 113 the amount of the supplied liquid film or the weight of the corresponding liquid film as the state of the liquid film.

(12) In each of the embodiments and the modifications described above, the robot controller 111 uses the lookup table LUT to obtain the acceleration/deceleration tolerance RA and the like for moving the hand 73 in correspondence to the type of the substrate W and the state of the liquid film. In this regard, the robot controller 111 may use the lookup table LUT to obtain the acceleration/deceleration tolerance RA and the like for moving the hand 73 in correspondence to the state of the liquid film.

(13) In the embodiments and the modifications described above, the single-wafer processing chamber SW2 performs the dry treatment on the substrates W with the supercritical fluid. In this regard, the single-wafer processing chamber SW2 may include a holding rotator 141 and a nozzle 143 like the single-wafer processing chamber SW1. In this case, the eleven single-wafer processing chambers SW1, SW2 each supply pure water and IPA to the substrates W in this order, for example, and then perform dry treatment (spin drying) on the substrates W.

The present invention may be embodied in other specific forms without departing from the spirit or essential attributes thereof and, accordingly, reference should be made to the appended claims, rather than to the foregoing specification, as indicating the scope of the invention.

What is claimed is:

1. A substrate transporting robot that transports a substrate, comprising:
a hand configured to support the substrate in a horizontal posture;
a moving mechanism configured to move the hand in a horizontal direction; and
a controller, wherein
the controller is configured to:
cause the hand to support the substrate, on whose top face a liquid film is formed,
obtain a first range of an acceleration/deceleration for moving the hand in correspondence to a state of the liquid film, and
cause the moving mechanism to move the hand at an acceleration/deceleration within the first range.

2. The substrate transporting robot according to claim 1, further comprising:
a sensor configured to detect the state of the liquid film; wherein
the controller is configured to
obtain the first range of the acceleration/deceleration for moving the hand in correspondence to a state of the liquid film detected by the sensor.

3. The substrate transporting robot according to claim 2, wherein
the sensor is a weight sensor provided on the hand and configured to measure a weight, and
the controller is configured to
obtain the first range of the acceleration/deceleration for moving the hand in correspondence to a weight of the liquid film measured by the weight sensor.

4. The substrate transporting robot according to claim 3, wherein
the hand includes a hand body, and
a plurality of contacting parts on an upper surface of the hand body that receive a peripheral portion of the substrate, and
the weight sensor is provided between any one of the contacting parts and the hand body.

5. The substrate transporting robot according to claim 3, wherein
the first range of the acceleration/deceleration is within a tolerance of the acceleration/deceleration narrower than a limit range of the acceleration/deceleration where the liquid does not spill from the substrate due to movement of the liquid of the liquid film,
the controller monitors a weight change amount of the liquid moving on the top face of the substrate at a measurement position of the weight sensor during movement of the hand in accordance with a weight value measured by the weight sensor, and
controls the acceleration/deceleration of the hand so that the weight change amount falls within a range of the change amount in correspondence to the tolerance of the acceleration/deceleration.

6. The substrate transporting robot according to claim 1, wherein
the controller obtains the first range of the acceleration/deceleration for moving the hand in correspondence to the state of the liquid film and type of the substrate.

7. The substrate transporting robot according to claim 6, wherein
the type of the substrate includes substrate wettability.

8. The substrate transporting robot according to claim 6, wherein
the controller obtains the first range of the acceleration/deceleration for moving the hand in correspondence to the state of the liquid film and the type of the substrate using a lookup table.

9. The substrate transporting robot according to claim 1, further comprising:
a sensor configured to detect the state of the liquid film; and
a memory configured to store a plurality of pieces of relationship data, each of which differs in the state of the liquid film, wherein
each of the plurality of pieces of relationship data has a relation between an amount of change in the state of the liquid film and the acceleration/deceleration and the first range of the acceleration/deceleration in the relation,
the controller is configured to
obtain the amount of change in the state of the liquid film, detected by the sensor, when the moving mechanism moves the hand at a preset acceleration/deceleration,
match the preset acceleration/deceleration and the obtained amount of change in the state of the liquid film with the relation of the plurality of pieces of relational data, thereby extracting one piece of the relational data having the optimal relation from the plurality of pieces of relational data, and
obtain the first range of the acceleration/deceleration that the one piece of the relation data has.

10. The substrate transporting robot according to claim 1, further comprising:
a rotation mechanism configured to rotate the hand around a vertical axis, wherein
the controller obtains a second range of a rotation acceleration/deceleration for rotating the hand in correspondence to the state of the liquid film, and causes the rotation mechanism to rotate the hand within the second range.

11. A substrate treating system for treating a substrate, comprising:
a substrate transporting robot that transports the substrate; wherein
the substrate transporting robot includes:
a hand configured to support the substrate in a horizontal posture;
a moving mechanism configured to move the hand in a horizontal direction; and
a controller, and
the controller is configured to:
cause the hand to support the substrate, on whose top face a liquid film is formed,
obtain a first range of an acceleration/deceleration for moving the hand in correspondence to a state of the liquid film, and
cause the moving mechanism to move the hand at an acceleration/deceleration within the first range.

12. A method of controlling a substrate transporting robot that transports a substrate,
the substrate transporting robot including:
a hand configured to support the substrate in a horizontal posture; and
a moving mechanism configured to move the hand in a horizontal direction,
the method comprising:
causing the hand to support the substrate, on whose top face a liquid film is formed;
obtaining a first range of an acceleration/deceleration for moving the hand in correspondence to a state of the liquid film; and
causing the moving mechanism to move the hand at an acceleration/deceleration within the first range.
